(19) United States
(12) Patent Application Publication
(10) Pub. No.: US 2026/0305405 A1
(43) Pub. Date: Oct. 1, 2026

(54) ELECTRONIC DEVICES AND METHODS OF MANUFACTURING ELECTRONIC DEVICES

(71) Applicant: Amkor Technology Singapore Holding Pte. Ltd.

(72) Inventors: Hun Jung Lim, Sejong (KR); Gook Jin Jung, Gwangju (KR); Young Seob Shin, Gwangju (KR)

(73) Assignee: Amkor Technology Singapore Holding Pte. Ltd., (omitted)

(21) Appl. No.: 19/090,213

(22) Filed: Mar. 25, 2025

(51) Int. Cl. H01L 23/538; H01L 23/00; H01L 23/31; H01L 23/498

(52) U.S. Cl. CPC H10W 70/65; H10W 42/121; H10W 70/611; H10W 70/635; H10W 74/131; H10W 90/701

(57) ABSTRACT

In one example, an electronic device can include a substrate comprising an integrated passive device (IPD) embedded in a central region of the substrate. An electronic module can be coupled to the substrate. The electronic module can comprise a first electronic component including a power region oriented towards the substrate, a transistor region over the power region, a signal region over the transistor region, and a support structure over the transistor region. An upper redistribution structure can be coupled to the support structure. A vertical interconnect can be disposed lateral to a sidewall of the first electronic component and coupled to the upper redistribution structure. Second electronic components can be disposed over the electronic module and coupled to the upper redistribution structure. A lid can be coupled to an upper side of the second electronic components. Other examples and related methods are also disclosed herein.

### TECHNICAL FIELD

The present disclosure relates, in general, to electronic devices, and more particularly, to electronic devices and methods for manufacturing electronic devices.

### BACKGROUND

Prior electronic packages and methods for forming electronic packages are inadequate, resulting in, for example, excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1A shows a cross-sectional view of an example electronic device.

FIG. 1B shows a cross-sectional view of an example electronic component having a backside power network.

FIGS. 2A to 2O show an example method for making an electronic device.

FIG. 3 shows a cross-sectional view of an example electronic device.

FIG. 4 shows a cross-sectional view of an example electronic device.

FIG. 5 shows a cross-sectional view of an example electronic component.

FIGS. 6A-6R show an example method for making an electronic component.

FIG. 7 shows a cross-sectional view of an example electronic device.

The following discussion provides various examples of electronic devices and methods of manufacturing electronic devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and “including” are “open ended” terms and specify the presence of the stated features, but do not preclude the presence or addition of one or more other features.

The terms “first,” “second,” etc. may be used herein to describe various elements. These elements are not limited by these terms. These terms are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or to describe two elements indirectly coupled by one or more other elements. For example, if element A is coupled to element B, then element A can be contacting element B or indirectly coupled to element B by an intervening element C. Similarly, the terms “over” or “on” may be used to describe two elements directly contacting each other or describe two elements indirectly coupled by one or more other elements. As used herein, the term “coupled” can refer to a mechanical coupling or an electrical coupling.

Various method steps are presented herein in an example order. The order of presentation for method steps is used only as an example. Various examples can perform method steps in other viable orders.

### DESCRIPTION

An example electronic device comprises a cavity substrate comprising inner sidewalls and a recessed side that define an aperture. An integrated passive device (IPD) is embedded in the cavity substrate with the recessed side disposed over the IPD. An electronic module can be disposed in the aperture and over the IPD. The electronic module can include a lower redistribution structure coupled to the recessed side of the cavity substrate, and a first electronic component including a power region coupled to the lower redistribution structure, a transistor region over the power region, and a signal region over the transistor region. An upper redistribution structure can be coupled to an upper side of the first electronic component/A vertical interconnect can be disposed lateral to a sidewall of the first electronic component, the vertical interconnect coupled to the lower redistribution structure and the upper redistribution structure. Second electronic components can be disposed over the electronic module and coupled to the upper redistribution structure. A lid can be coupled to an upper side of the second electronic components.

Another electronic device can include a substrate including an integrated passive device (IPD) embedded in a central region of the substrate. An electronic module can be coupled to the substrate. The electronic module can comprise a first electronic component including a power region oriented towards the substrate, a transistor region over the power region, a signal region over the transistor region, and a support structure over the transistor region. An upper redistribution structure can be coupled to the support structure. A vertical interconnect can be disposed lateral to a sidewall of the first electronic component and coupled to the upper redistribution structure. Second electronic components can be disposed over the electronic module and coupled to the upper redistribution structure. A lid can be coupled to an upper side of the second electronic components.

An example method of manufacturing an electronic device can include the step of providing a substrate including an integrated passive device (IPD) embedded in a central region of the substrate. An electronic module can be provided over the substrate and can include a lower redistribution structure coupled to the central region of the substrate, a first electronic component including a power region coupled to the lower redistribution structure, a transistor region over the power region, and a signal region over the transistor region. An upper redistribution structure can be coupled to an upper side of the first electronic component. The example method can include the steps of providing second electronic components over the upper redistribution structure, and providing a lid coupled to the second electronic components.

Other examples are included in the present disclosure. Such examples may be found in the figures, in the claims, or in the description of the present disclosure.

Various example electronic devices and related techniques can include embedded fan-out wafer-level-packages with backside power delivery. Wide redistribution layers (RDL) can be used to enable direct interconnection between processing die and memory die. A wide metal heat spreader can support thermal management. Resulting devices can comprise a high speed (e.g., short interconnection path and high input/output (i/o) count), effective power delivery via copper pillars and integrated passive devices, and decreased power consumption. In some examples, passive devices can be embedded into a cavity substrate to facilitate a direct interconnection with a processing die at the core of a PCB though pillars or posts.

Example electronic devices can enhance flexibility with stacking techniques for advanced packaging. Memory die can be stacked over a logic die, for example. Thermal release can be improved using an ultrawide heat spreader, and total thickness can be reduced using embedded packages. Some examples can exhibit improved electrical performance in the form of reduced impedance and reduced signal loss. Manufacturing costs can also be reduced by including a substrate body for size control.

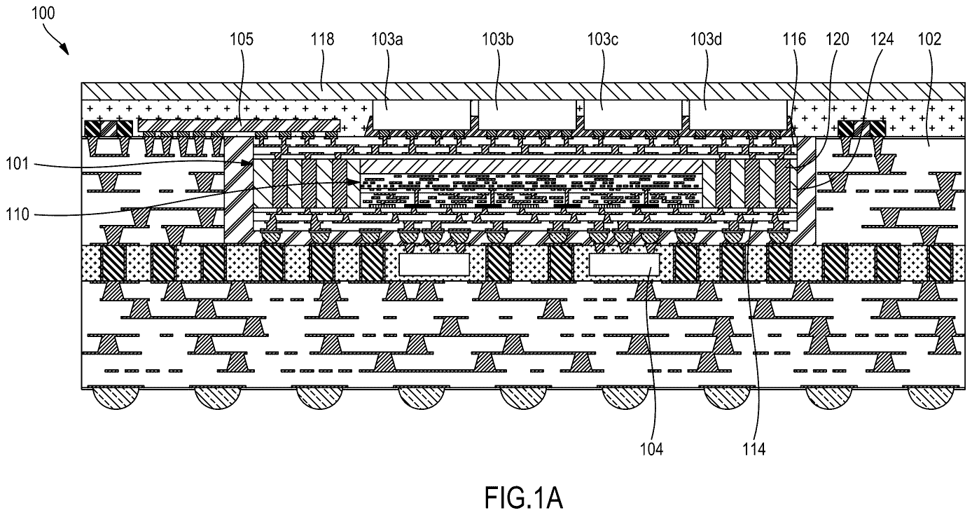

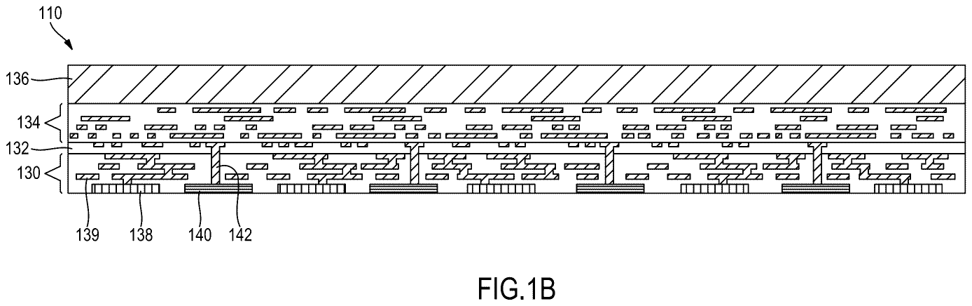

FIG. 1A shows a cross-sectional view of an example electronic device 100. In the example shown in FIG. 1, electronic device 100 comprises electronic module 101 embedded in cavity substrate 102. Electronic components 103a, 103b, 103c, 103d can be stacked over electronic module 101. Electronic components 104 (e.g., integrated passive devices (IPDs)) can be embedded in cavity substrate 102 and electrically coupled to electronic component 110 of electronic module 101.

Electronic module 101 can comprise electronic component 110 coupled to outer redistribution structure 114 and inner redistribution structure 116. Encapsulant 124 can be disposed around a perimeter of electronic component 110. Vertical interconnects 120 can be disposed around the sides of electronic component 110 and can extend vertically though encapsulant 124. Outer redistribution structure 114 can be coupled to inner redistribution structure 116 through vertical interconnects 120. Electronic component 105 (e.g., a bridge die) can couple cavity substrate 102 with inner redistribution structure 116. Lid 118 can be coupled to electronic components 103a-103d and can cover an upper side of electronic device 100.

FIG. 1B shows electronic component 110 of electronic device 100 in greater detail. Electronic component 110 can comprise power region 130, transistor region 132, and signal region 134. Power region 130 can include power contact pads 138 and power conductive layers 139. Power region 130 can also be referred to as a power network and can deliver current or voltage for use in electronic component 110.

Signal region 134 can be disposed over power region 130 and transistor region 132. Signal region 134 can also be referred to as a signal network. Signal region 134 can enable communication of signals from transistor region 132. Transistor region 132 can comprise silicon (Si), or other semiconductor material, and can be between signal region 134 and power region 130. Conductive vias 142 can extend through power region 130 and through transistor region 132 to couple signal region 134 with signal contact pads 140. In some examples, the combined thickness of power region 130, transistor region 132, and signal region 134 can range from approximately 40 nanometer (nm) to approximately 1000 micrometer (μm), approximately 200 nm to approximately 500 μm, approximately 500 nm to approximately 20 μm, approximately 1000 nm to approximately 40 μm, approximately 10 μm to approximately 20 μm, approximately 800 nm to approximately 1200 nm, or approximately 800 nm to approximately 1000 nm.

Electronic component 110 can further include support structure 136. Support structure 136 can be disposed over signal region 134. For example, signal region 134 can be between support structure 136 and transistor region 132. Support structure 136 can comprise semiconductor material (e.g., Si), mold, glass, or other suitable material, and can provide structural support to electronic component 110. In some examples, a thickness of support structure 136 can range from approximately 10 μm to approximately 100 μm, approximately 100 μm to approximately 1000 μm, approximately 400 μm to 800 μm, or approximately 350 μm to approximately 500 μm.

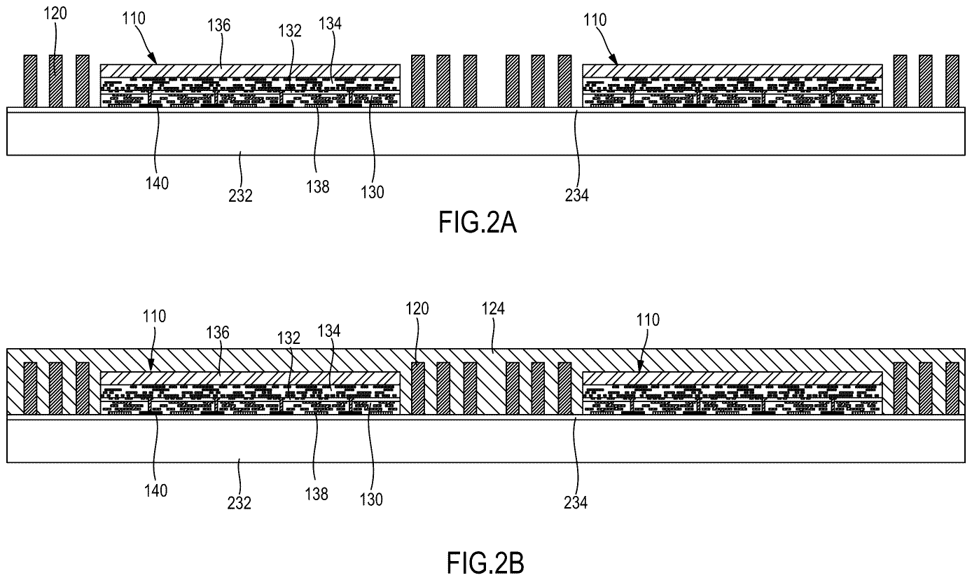

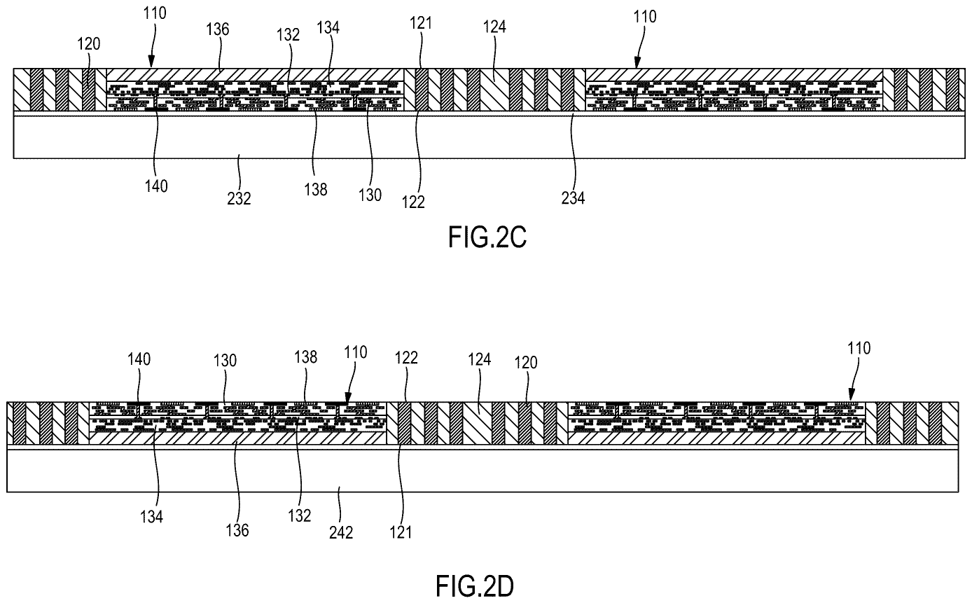

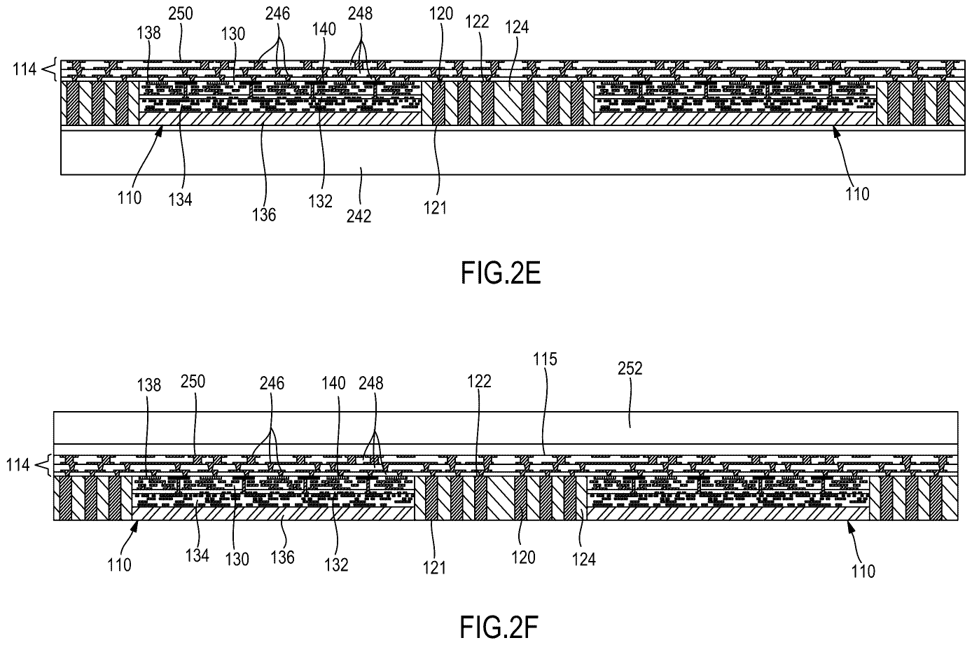

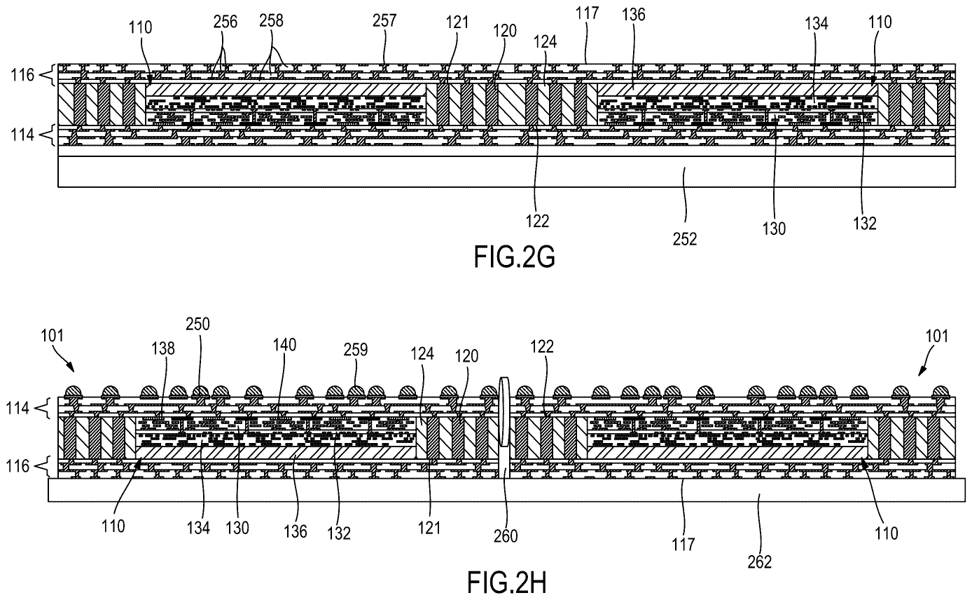

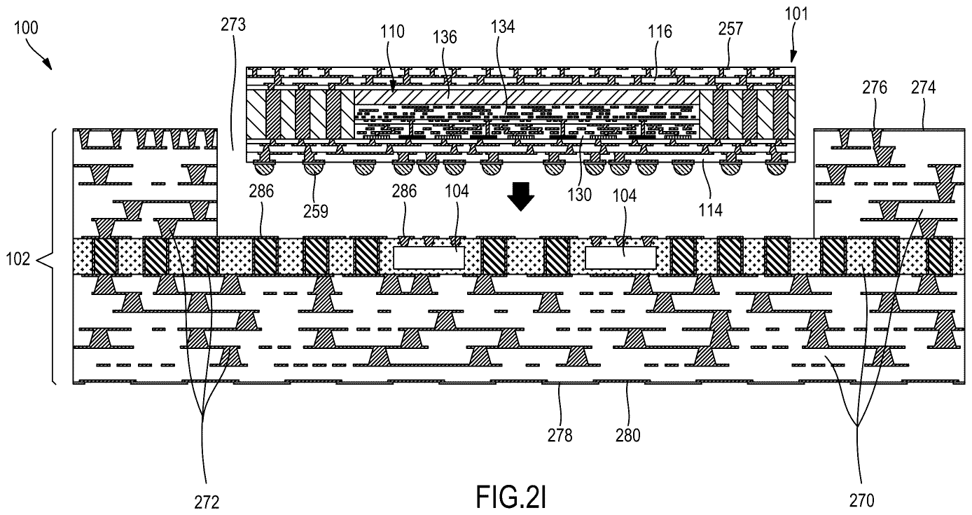

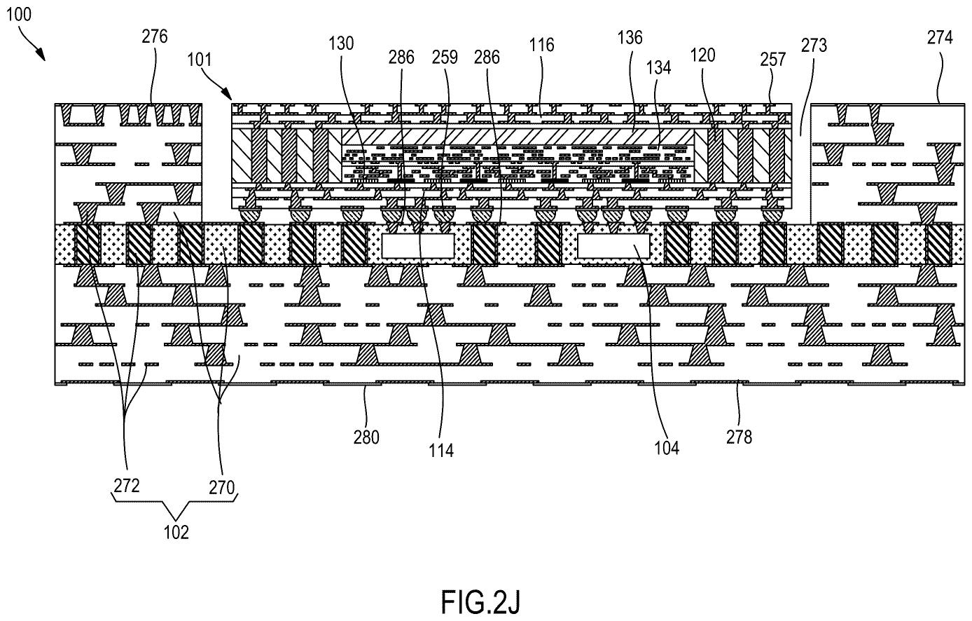

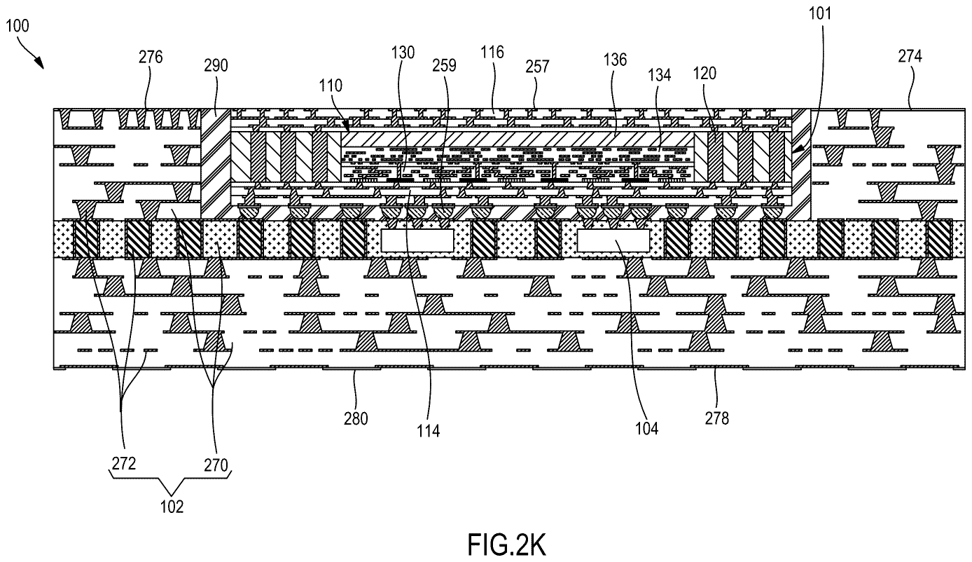

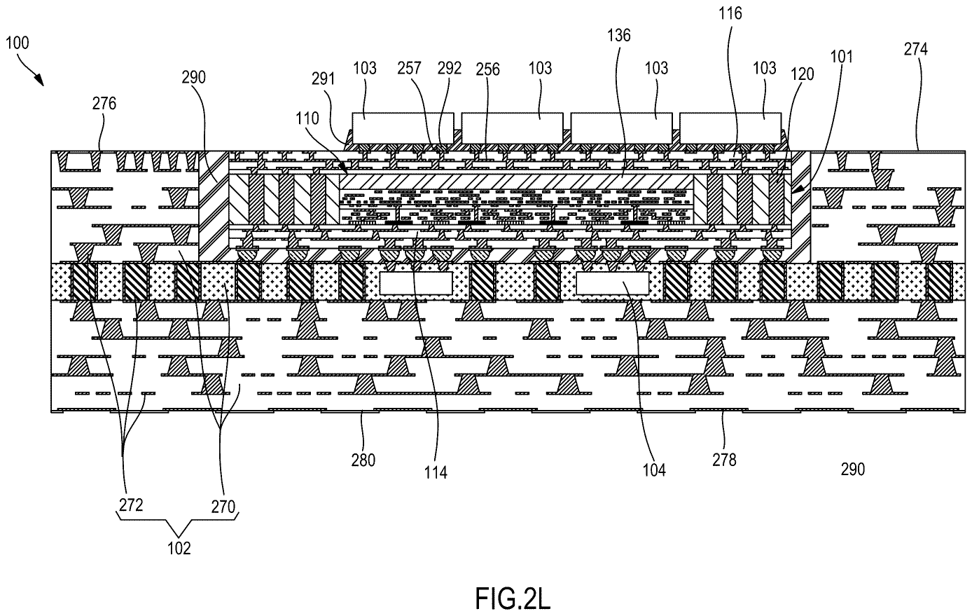

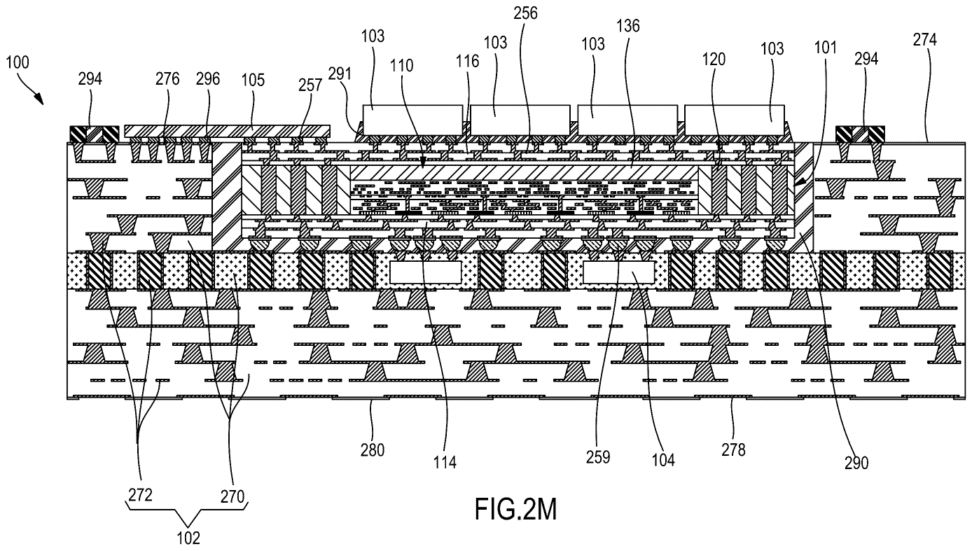

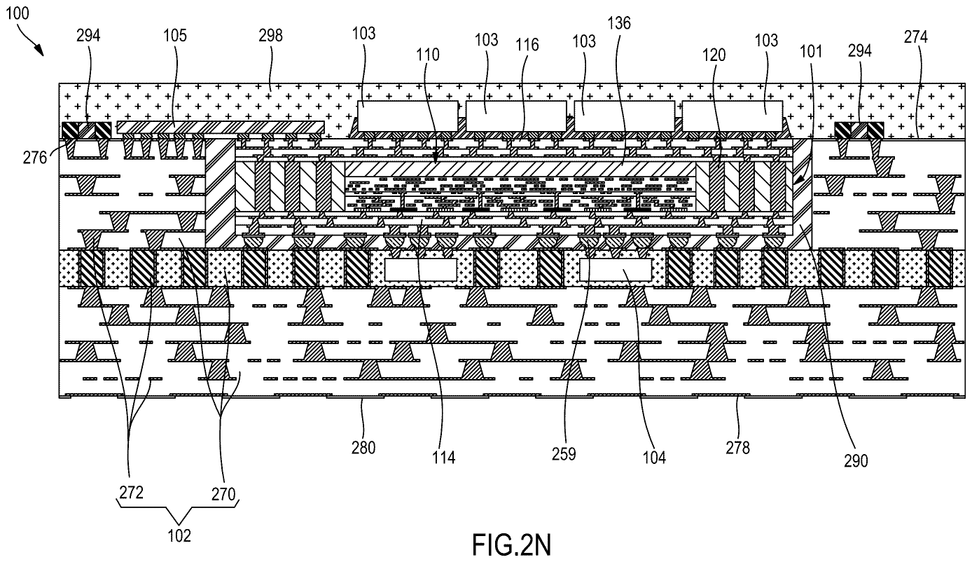

FIGS. 2A to 2O show an example method for manufacturing electronic module 101. FIG. 2A shows a cross-sectional view of electronic module 101 of electronic device 100 at an early stage of manufacture. In the example shown in FIG. 2A, vertical interconnects 120 and electronic component 110 are provided on the upper side of carrier 232.

Carrier 232 can comprise a substantially planar plate. In some examples, carrier 232 can comprise or be referred to as a plate, a board, a wafer, a panel, or a strip. For example, carrier 232 can be provided as a round wafer or a square or rectangular panel. In some examples, the thickness of carrier 232 can range from approximately 300 micrometers (μm) to approximately 1000 μm, and the width of carrier 232 can range from approximately 100 millimeters (mm) to approximately 300 mm. In some examples, the width of carrier 232 can range from approximately 200 millimeters mm to approximately 600 mm. In some examples, the width of carrier 232 can be greater than 600 mm. As used herein with numeric values, the term “approximately” can mean +/−5%, +/−10%, +/−15%, +/−20%, or +/−25%. Carrier 232 can support multiple electronic modules 101 during processing.

In some examples, carrier 232 can comprise a temporary bond layer 234 provided on the upper side of carrier 232. In some examples, temporary bond layer 234 can comprise or be referred to as a temporary bonding film, a temporary bonding tape, or a temporary adhesive coating. For example, temporary bonding layer 234 can comprise a heat release tape (or film) or an optical release tape (or film), wherein the adhesive strength is weakened or removed by heat or light, respectively. The temporary bond layer 234 can facilitate separation of electronic module 101 from carrier 232 at a later stage of manufacture.

In accordance with various examples, vertical interconnects 120 can be provided in an edge or perimeter area relative to electronic component 110. For example, vertical interconnects 120 can be provided about a perimeter that corresponds to a location where each electronic component 110 will be mounted. Vertical interconnects 120 can be spaced apart from each other in a row or column arrangement. Vertical interconnects 120 can be provided by electrolytic plating, electroless plating, sputtering, PVD, CVD, MOCVD, ALD, LPCVD, or PECVD. In some examples, vertical interconnects 120 can be made of copper, gold, silver, palladium, or nickel. In some examples, vertical interconnects 120 can be preformed structures that are formed prior to being located over carrier 232. Vertical interconnects 120 can comprise posts, pillars, vertical wires, bumps, or solder-coated-metallic-core-balls. In some examples, the height of vertical interconnect 120 can range from approximately 50 μm to approximately 400 μm.

In accordance with various examples, electronic component 110 can be coupled to the upper side of carrier 232. Temporary bond layer 234 of carrier 232 can be coupled to an exposed side of power region 130 of electronic component 110. Power contact pads 138 and signal contact pads 140 can be oriented towards carrier 232. In some examples, electronic component 110 can be provided and vertical interconnects 120 can subsequently be provided around the sidewalls of electronic component 110. In some examples, vertical interconnects 120 can be formed or provided over carrier 232 and electronic component 110 can subsequently be placed in a central opening between vertical interconnects 120. Vertical interconnects 120 can have a height greater than or approximately equal to the height of electronic component 110.

FIG. 2B shows a cross-sectional view of electronic module 101 of electronic device 100 at a later stage of manufacture. In the example shown in FIG. 2B, encapsulant 124 can be provided over electronic component 110, vertical interconnects 120, and carrier 232.

In various examples, encapsulant 124 can comprise or be referred to as a body or a molding. In some examples, encapsulant 124 can comprise an epoxy mold compound, a resin, or an organic polymer with an inorganic filler, a curing agent, a catalyst, a coupling agent, a colorant, or a flame retardant. Encapsulant 124 can be provided by compression molding, transfer molding, liquid body molding, vacuum lamination, paste printing, film assist molding, or any other suitable encapsulation technique.

In some examples, encapsulant 124 can be coupled to the upper side and sidewalls of electronic component 110, and the upper side and sidewalls of vertical interconnects 120. Encapsulant 124 can be disposed over support structure 136 of electronic component 110. Encapsulant 124 can be coupled to the lateral sides of support structure 136, signal region 134, transistor region 132, and power region 130 in various examples.

FIG. 2C shows a cross-sectional view of electronic module 101 of electronic device 100 at a later stage of manufacture. In the example shown in FIG. 2C, an upper portion of encapsulant 124 is removed and distal side (or distal end) 121 of vertical interconnects 120 are exposed. Distal side 121 of vertical interconnects can be farther from or distal from carrier 232, and proximate side (or proximate end) 122 of vertical interconnects 120 can be closer to or proximate carrier 232. In some examples, the upper side of electronic component 110 (e.g., a portion of support structure 136) and/or an upper portion of vertical interconnects 120 also be removed to reduce overall thickness of module 101.

In accordance with various examples, the upper portion of encapsulant 124, support structure 136, or vertical interconnects 120 can be removed by grinding, for example. In some examples, after removal of the upper portion of encapsulant 124, the upper side of encapsulant 124, the upper side of electronic component 110, and the distal side 121 of vertical interconnects 120 can be substantially coplanar. As used herein, the term substantially coplanar can mean within manufacturing tolerances of coplanarity. In some examples, a portion of encapsulant 124 can remain over the upper side of electronic component 110. For example, encapsulant 124 can be on support structure 136 of electronic component 110. In some examples, a thickness of encapsulant 124 can range from approximately 10 μm to approximately 2500 μm, approximately 30 μm to approximately 1500 μm, approximately 100 μm to approximately 1000 μm, approximately 100 μm to approximately 500 μm, approximately 100 μm to approximately 140 μm, or approximately 100 μm to approximately 120 μm.

FIG. 2D shows a cross-sectional view of electronic module 101 of electronic device 100 at a later stage of manufacture. In the example shown in FIG. 2D, carrier 232 can be removed and carrier 242 can be coupled to encapsulant 124, distal side 121 of vertical interconnects 120, and support structure 136 of electronic component 110. Structures and techniques of carrier 242 can be similar to or the same as those described above for carrier 232. In some examples, encapsulant 124, distal side 121 of vertical interconnects 120, and support structure 136 of electronic component 110 can be coupled to carrier 242 by a temporary adhesive, film, or tape, similar to temporary bond layer 234 of carrier 232. Electronic component 110 can have support structure 136 oriented towards carrier 242. Power region 130 of electronic component 110 can be oriented away from carrier 242. Removal of carrier 232 can expose power pads 138 and signal pads 140 of electronic components 110 and proximate end 122 of vertical interconnects 120.

FIG. 2E shows a cross-sectional view of electronic module 101 of electronic device 100 at a later stage of manufacture. In the example shown in FIG. 2E, outer redistribution structure 114 is provided over encapsulant 124, proximate side 122 of vertical interconnects 120, and power region 130 of electronic component 110.

In accordance with various embodiments, outer redistribution structure 114 can comprise dielectric structure 248 and conductive structure 246. Dielectric structure 248 can comprise one or more dielectric layers made of dielectric material (e.g., polymer, polyimide (PI), benzocyclobutene (BCB), polybenzoxazole (PBO), bismaleimide triazine (BT), resin, Ajinomoto Buildup Film (ABF), Si3N4, SiO2, SiON, etc.) and interleaved between layers of conductive structure 246. Dielectric structure 248 can be provided by PVD, CVD, MOCVD, ALD, LPCVD, PECVD, or any other suitable deposition process. Conductive structure 246 can comprise one or more conductive layers defining signal distribution elements (e.g., traces, vias, pads, conductive paths, UBMs, etc.) interleaved between layers of dielectric structure 248. Conductive structure 246 can comprise Al, Cu, Au, Ag, Ni, Pd, Ti, TiW, or other suitable conductive material. Conductive structure 246 can be formed using PVD, CVD, MOCVD, ALD, LPCVD, PECVD, electrolytic plating, electroless plating process, or any other suitable metal deposition process. Conductive structure 246 can be coupled to power contact pads 138 and signal contact pads 140 of electronic component 110. Conductive structure 246 can distribute power and electrical signals in a vertical direction and a lateral direction through outer redistribution structure 114.

Conductive structure 246 can comprise outward terminals 250. Outward terminals 250 can be provided at the upper side of outer redistribution structure 114 (i.e., the side opposite electronic component 110). In some examples, outward terminals 250 can comprise or be referred to as pads, lands, UBMs, or studs. In some examples, the exposed or upper sides, as shown in FIG. 2E, of outward terminals 250 can protrude from the upper side of dielectric structure 248. In some examples, the exposed or upper sides of outward terminals 250 can be substantially coplanar with the upper side of dielectric structure 248. In some examples, the exposed or upper sides of outward terminals 250 can be recessed with respect to the upper side of dielectric structure 248. Conductive structures (e.g., traces and vias) of conductive structure 246 can electrically couple electronic component 110 and vertical interconnects 120 with outward terminals 250. In some examples, individual layers of dielectric structure 248 and conductive structure 246 can range in thickness from approximately 2 μm to approximately 25 μm, approximately 6 μm to approximately 30 μm in thickness, or from approximately 18 μm to approximately 90 μm in thickness. Conductive structure 246 of outer redistribution structure 114 can electrically couple signal pads 140 of electronic component 110 to vertical interconnects 120.

In various examples, outer redistribution structure 114 can comprise a redistribution layer (“RDL”) substrate. RDL substrates can comprise one or more conductive redistribution layers and one or more dielectric layers and (a) can be formed layer by layer over an electronic device to where the RDL substrate is coupled, or (b) can be formed layer by layer over a carrier that can be entirely removed or at least partially removed after the electronic device and the RDL substrate are coupled together. RDL substrates can be manufactured layer by layer as a wafer-level substrate on a round wafer in a wafer-level process, and/or as a panel-level substrate on a rectangular or square panel carrier in a panel-level process. RDL substrates can be formed in an additive buildup process and can include one or more dielectric layers alternatingly formed with one or more conductive layers and define respective conductive redistribution patterns or traces configured to collectively (a) fan-out electrical traces outside the footprint of the electronic device, and/or (b) fan-in electrical traces within the footprint of the electronic device. The conductive patterns can be formed using a plating process such as, for example, an electroplating process or an electroless plating process. The conductive patterns can comprise a conductive material such as, for example, copper or other plateable metal. The locations of the conductive patterns can be made using a photo-patterning process such as, for example, a photolithography process and a photoresist material to form a photolithographic mask. The dielectric layers of the RDL substrate can be patterned with a photo-patterning process, and can include a photolithographic mask through where light is exposed to photo-pattern desired features, such as vias in the dielectric layers. The dielectric layers can be made from photo-definable organic dielectric materials such as, for example, polyimide (PI), benzocyclobutene (BCB), or polybenzoxazole (PBO). Such dielectric materials can be spun-on or otherwise coated in liquid form, rather than attached as a pre-formed film. To permit proper formation of desired photo-defined features, such photo-definable dielectric materials can omit structural reinforcers or can be filler-free, without strands, weaves, or other particles, and could interfere with the light from the photo-patterning process. In some examples, such filler-free characteristics of filler-free dielectric materials can permit a reduction of the thickness of the resulting dielectric layer. Although the photo-definable dielectric materials described above can be organic materials, in some examples the dielectric materials of the RDL substrates can comprise one or more inorganic dielectric layers. Some examples of inorganic dielectric layers can comprise silicon nitride (Si3N4), silicon oxide (SiO2), and/or SiON. The inorganic dielectric layers can be formed by growing the inorganic dielectric layers using an oxidation or nitridization process instead of using photo-defined organic dielectric materials. Such inorganic dielectric layers can be filler-free, without strands, weaves, or other dissimilar inorganic particles. RDL substrates can omit a permanent core structure generally associated with laminate substrates.

In some examples, upper redistribution structure 114 can comprise a pre-formed or laminate substrate. Pre-formed substrates can be manufactured prior to attachment to an electronic device and can comprise dielectric layers between respective conductive layers. The conductive layers can comprise copper and can be formed using an electroplating process. The dielectric layers can be relatively thicker non-photo-definable layers, can be attached as a pre-formed film rather than as a liquid, and can include a resin with fillers such as strands, weaves, and/or other inorganic particles for rigidity and/or structural support. Since the dielectric layers are non-photo-definable, features such as vias or openings can be formed by using a drill or laser. In some examples, the dielectric layers can comprise a prepreg material or an Ajinomoto buildup film (ABF). The pre-formed substrate can include a permanent core structure or carrier such as, for example, a dielectric material comprising bismaleimide triazine (BT) or FR4, and dielectric and conductive layers can be formed on the permanent core structure. In other examples, the pre-formed substrate can comprise a coreless substrate and omit the permanent core structure, and the dielectric and conductive layers can be formed on a sacrificial carrier, which can be removed after formation of the dielectric and conductive layers and before attachment to the electronic device. The pre-formed substrate can be referred to as a printed circuit board (PCB) or a laminate substrate. Such pre-formed substrate can be formed through a semi-additive or modified-semi-additive process.

FIG. 2F shows a cross-sectional view of electronic module 101 of electronic device 100 at a later stage of manufacture. In the example shown in FIG. 2F, carrier 252 is coupled to outer side 115 of outer redistribution structure 114 and carrier 242 is removed. Structures and techniques of carrier 252 can be similar to or the same as those described above for carrier 232 in some examples. Support structure 136 of electronic component 110 can be oriented away from carrier 252 with outer redistribution structure 114 between carrier 252 and electronic component 110. In some examples, outer redistribution structure 114 can be coupled to carrier 252 by a temporary adhesive, film, or tape, similar to temporary bond layer 234 of carrier 232. Removal of carrier 242 can expose support structure 136 of electronic component 110 and distal side 121 of vertical interconnects 120.

FIG. 2G shows a cross-sectional view of electronic module 101 of electronic device 100 at a later stage of manufacture. In the example shown in FIG. 2G, inner redistribution structure 116 is provided over support structure 136 of electronic components 110, encapsulant 124, and distal end 121 vertical interconnects 120.

Inner redistribution structure 116 can be provided using techniques, structures, and materials similar to or the same as those described above for outer redistribution structure 114. Inner redistribution structure 116 can comprise conductive structure 256 and dielectric structure 258. The various components of conductive structure 256 and dielectric structure 258 can be interleaved with one another. Conductive structure 256 can be coupled to distal end 121 of vertical interconnects 120.

Conductive structure 256 can comprise inner terminals 257. Inner terminals 257 can be provided at distal (or upper as oriented in FIG. 2G) side 117 of inner redistribution structure 116 (i.e., along the side opposite carrier 252). In some examples, inner terminals 257 can comprise or be referred to as pads, lands, UBMs, or studs. In some examples, the exposed or upper sides, as shown in FIG. 2G, of inner terminals 257 can protrude from the upper side of dielectric structure 258. In some examples, the exposed or upper sides of inner terminals 257 can be substantially coplanar with the upper side of dielectric structure 258. In some examples, the exposed or upper sides of inner terminals 257 can be recessed with respect to the upper side of dielectric structure 258. Conductive structures (e.g., traces and vias) of conductive structure 256 can electrically couple vertical interconnects 120 with inner terminals 257.

FIG. 2H shows a cross-sectional view of electronic module 101 of electronic device 100 at a later stage of manufacture. In the example shown in FIG. 2H, support 262 is coupled to distal side 117 of inner redistribution structure 116, carrier 252 is removed from outer redistribution structure 114, and module interconnects 259 are provided. In accordance with various examples, a singulation can then performed to provide individual electronic modules 101.

In some examples, module interconnects 259 can be provided on outward terminals 250 of outer redistribution structure 114. Module interconnects 259 can comprise signal interconnects and power interconnects electrically coupled to the signal network 134 and power network 130, respectively, of electronic component 110. Module interconnects 259 can comprise or be referred to as conductive pillars, conductive balls, conductive bumps, solder balls, or conductive pillars with solder caps. In some examples, a conductive pillar can be provided on outward terminals 250 by plating or depositing Cu, Al, Au, Ag, Ni, or SnAg on outward terminals 250. In some examples, flux or flowable material can be provided on outward terminals 250, conductive balls are dropped on the flux, and the conductive balls can then be provided on outward terminals 250 through a reflow process. In some examples, the conductive balls can comprise Sn, Ag, Pb, Cu, Sn—Pb, Sn37-Pb, Sn95-Pb, Sn—Pb—Ag, Sn—Cu, Sn—Ag, Sn—Au, Sn—Bi, or Sn—Ag—Cu. In some examples, the thicknesses or widths of module interconnects 259 can range from approximately 0.01 mm to approximately 0.5 mm. Component interconnects 259 can serve to couple electronic module 101 to other elements of electronic device 100.

In various examples, a singulation process can be performed to saw electronic modules 101 along scribe lines (or saw streets) 260, thereby separating individual electronic modules 101 from one another. In some examples, a diamond blade or laser beam can be utilized for singulation. Singulation can include cutting or sawing through encapsulant 124, outer redistribution structure 114, and inner redistribution structure 116. After singulation the lateral sides of encapsulant 124, outer redistribution structure 114, and inner redistribution structure 116 can be substantially coplanar.

FIG. 2I shows a cross-sectional view of electronic device 100 at a later stage of manufacture. In the example shown in FIG. 2I, cavity substrate 102 can be provided.

In some examples, cavity substrate 102 can comprise conductive structure 272, dielectric structure 270, and aperture 273. In some examples, aperture 273 can be defined in a central region of cavity substrate 102. In some examples, cavity substrate 102 can comprise a pre-formed (e.g., laminate) substrate. In some examples, cavity substrate 102 can be an RDL substrate. Cavity substrate 102 can comprise a rectangular frame defining aperture 273 located at its center or within its perimeter. Although only one aperture 273 is shown in FIG. 2I, one or more apertures 273 can be positioned spaced apart from one another in various examples. In some examples, cavity substrate 102 can be symmetrically formed in left and right directions on the basis of aperture 273.

In accordance with various examples, cavity substrate 102 comprises dielectric structure 270 and conductive structure 272. In some examples, dielectric structure 270 can comprise or be referred to as one or more stacked dielectric layers. For instance, the one or more dielectric layers can comprise, one or more core layers, polymer layers, pre-preg layers, ABF layer, or solder mask layers stacked on each other. One or more layers or elements of conductive structure 272 can be interleaved with elements or layers of dielectric structure 270. In some examples, dielectric structure 270 can comprise FR4 (copper foil/glass fiber fabric/copper foil laminate), bismaleimide triazine (BT), polyimide (PI), benzocyclobutene (BCB), polybenzoxazole (PBO), phenolic resin, or Ajinomoto Buildup Film (ABF), mold compound, or glass. The thickness of individual layers of dielectric structure 270 can range from approximately 3 μm to approximately 1400 μm.

In some examples, a core of dielectric structure 270 can have thickness of between approximately 100 μm and approximately 1400 μm, between approximately 200 μm and 1250 μm, between approximately 400 μm and 800 μm, of approximately 200 μm, of approximately 820 μm, or of approximately 1250 μm. In some examples, individual layers of dielectric structure 270 (e.g., ABF or prepreg layers) can be laminated to the core structure and/or to one another. The laminated layers of dielectric structure 270 can each have a thickness between approximately 3 μm and approximately 40 μm, between approximately 10 μm and approximately 50 μm, between approximately 25 μm and approximately 40 μm, between approximately 25 μm and approximately 35 μm, of approximately 20 μm, of approximately 25 μm, or of approximately 33 μm.

In some examples, the outermost dielectric layer on each side of cavity substrate 102 can comprise a solder mask material, which in some examples, can be different from the material of the laminated layers and/or the material of the core. In some examples, the solder mask (or solder resist) layers can be provided by screen printing and can have a thickness of between approximately 10 μm and approximately 50 μm, between approximately 20 μm and approximately 40 μm, between approximately 20 μm and approximately 30 μm, of approximately 20 μm, or of approximately 22 μm. In some examples, the thickness of the solder mask layer can be less than the thickness of the individual laminated layer(s). The combined thickness of the layers of dielectric structure 270 can define the thickness of cavity substrate 102. Dielectric structure 270 can maintain the shape of cavity substrate 102 and can structurally support conductive structure 272.

Conductive structure 272 can comprise or be referred to as one or more conductive layers defining signal distribution elements, traces, vias, pads, under bump metallization (UBM), redistribution layers (RDLs), conductive patterns, conductive paths, wiring patterns, or circuit patterns. In some examples, conductive structure 272 can comprise one or more layers of copper (Cu), aluminum (Al), tin (Sn), titanium (Ti), titanium tungsten (TiW), gold (Au), silver (Ag), nickel (Ni), palladium (Pd), or combinations or alloys thereof. The thickness of conductive structure 272 can range from approximately 5 μm to approximately 50 μm, 10 μm to approximately 30 μm, 15 μm to approximately 25 μm, or 18 μm to approximately 20 μm. The thickness of conductive structure 272 can refer to individual layers of conductive structure 272. In some examples, conductive structure 272 can have a trace width and trace spacing (width/spacing) of between approximately 5 μm/5 μm and approximately 50 μm/50 μm, between approximately 8 μm/8 μm and approximately 40 μm/40 μm, between approximately 9 μm/12 μm and approximately 25 μm/25 μm, or between approximately 9 μm/12 μm and approximately 20 μm/20 μm. Trace width is the width of individual traces of conductive structure 272 and trace spacing is the distance between adjacent traces of conductive structure 272.

Conductive structure 272 provides electrical signal paths (e.g., vertical paths and horizontal paths) through dielectric structure 270. Conductive structure 272 can be formed using, for example, sputtering, electroless plating, electroplating physical vapor deposition (PVD), chemical vapor deposition (CVD), metal organic chemical vapor deposition (MOCVD), atomic layer deposition (ALD), low pressure chemical vapor deposition (LPCVD), or plasma enhanced chemical vapor deposition (PECVD). Some portions of conductive structure 272 can be exposed from dielectric material (e.g., solder mask) of dielectric structure 270 at the upper side 274 of cavity substrate 102 as upper pads 276. Portions of conductive structure 272 can be exposed from dielectric material (e.g., solder mask) of dielectric structure 270 at the lower side 278 of cavity substrate 102 as lower pads 280.

In various examples, upper pads 276 can be exposed at the upper side 274 of cavity substrate 102. Upper pads 276 can comprise or be referred to as pads, lands, UBMs, studs, or bumps. Upper pads 276 can provide electrical contact between cavity substrate 102 and electronic components or conductive elements coupled thereto.

Lower pads 280 can be exposed from at lower side 278 of cavity substrate 102. Lower pads 280 can comprise or be referred to as pads, lands, UBMs, studs, or bumps. Lower pads 280 can provide electrical contact between cavity substrate 102 and electronic components or conductive elements coupled thereto.

Aperture 273 can be defined at the center of, or within a perimeter of, cavity substrate 102. In some examples, aperture 273 can comprise or be referred to as a cavity or an opening. In some examples, one or more apertures 273 can be spaced apart from one another in cavity substrate 102. Aperture 273 can be configured to partially penetrate cavity substrate, such that aperture 273 extends from the upper side 274 of cavity substrate 102 to an intermediate or recessed side of cavity substrate 102. Aperture 273 can extend partially through cavity substrate 102 in a vertical direction. In some examples, aperture 273 can be formed by removing a portion of cavity substrate 102. For example, aperture 273 can be formed by cutting such portion using a laser or a blade, or by etching. In some examples, cavity substrate 102 can be defined by a substantially hollowed rectangular frame. In some examples, a portion of electronic module 101 disposed in aperture 273 can be exposed when mounted on cavity substrate 102.

In some examples, conductive structure 272 can comprise interior pads 286 exposed along the floor of aperture 273. In some examples, module interconnects 259 can be coupled to interior pads 286. In some examples, cavity substrate 102 can comprise one or more embedded electronic component(s) 104. In some examples, electronic component 104 can comprise an IPD. Electronic components 104 can be coupled to electronic component 110 via conductive structure 272. In some examples, electronic components 104 can be located under and vertically aligned with electronic component 110. The location of electronic component(s) 104 can be configured to reduce the distance between electronic components 104 and electronic component 110, which can improve power distribution and electrical performance.

FIG. 2J shows a cross-sectional view of electronic device 100 at a later stage of manufacture. In the example shown in FIG. 2J, electronic module 101 can be coupled to cavity substrate 102. Interior pads 286 of cavity substrate 102 can be coupled to electronic module 101 through module interconnects 259. A thermocompression, reflow, or laser assisted bonding process can be performed to couple module interconnects 259 to interior pads 286. In some examples, the footprint of electronic component 110 vertically overlaps the footprint(s) of one or more electronic component(s) 104. A short electrical path can extend from electronic component 104 to electronic component 110 through component interconnects 259. In particular, electronic device 100 provides a short electrical distance between electronic component 104 and the power network 130 of electronic component 110, which can improve power distribution and electrical performance.

FIG. 2K shows a cross-sectional view of electronic device 100 at a later stage of manufacture. In the example shown in FIG. 2K, encapsulant 290 can be provided. Encapsulant 290 can be disposed around the lateral sides of module 101. Encapsulant 290 can fill a volume between module 101 and cavity substrate 102. Encapsulant 290 can be substantially coplanar with the upper side of module 101 and with the upper side of cavity substrate 102. Structures and techniques used to provide encapsulant 290 can be similar to or the same as those described above for encapsulants 124. In some examples, encapsulant 290 can comprise or be referred to as an underfill material.

FIG. 2L shows a cross-sectional view of electronic device 100 at a later stage of manufacture. In the example shown in FIG. 2L, electronic components 103 and underfill 291 can be provided. In various examples, electronic components 103 can be coupled to inner redistribution structure 116 of electronic module 101. In some examples, electronic components 103 can comprise memory die or packages and electronic component 110 can comprise a logic die (e.g., a central processing unit (CPU), graphics processing unit (GPU), or application specific integrated circuit (ASIC)). For example, one or more electronic component(s) 103 can comprise a high bandwidth memory (HBM) device. In some examples, the HBM device can include a controller die having a stack of memory die located thereon. The controller die and memory stack can be encapsulated. Component interconnects 292 of electronic components 103 can couple electronic components 103 to conductive structure 256 of inner redistribution structure 116. For example, a thermocompression, reflow, or laser assisted bonding process can be performed to couple component interconnects 292 with inner terminals 257 of inner redistribution structure 116. Underfill material 291 can be provided around the sides of component interconnects 292 and between the lower sides of electronic components 103 and the upper side of electronic module 101.

FIG. 2M shows a cross-sectional view of electronic device 100 at a later stage of manufacture. In the example shown in FIG. 2M, component 105 and electronic components 294 can be provided. In some examples, electronic components 294 can comprise die, chips, active or passive devices. Component 105 can be coupled to inner terminals 257 of inner redistribution structure 116 through component interconnects 296. Component 105 can also be coupled to contact pads 276 of conductive structure 272 of cavity substrate 102 through component interconnects 296. Electronic components 294 (e.g., passive devices) can be coupled to contact pads 276 of conductive structure 272. In some examples, component 105 can comprise a bridge die configured to electrically couple conductive structure 272 of cavity substrate 102 with the conductive structure 256 of electronic module 101 through a short communication path.

In some examples, the bridge die can include a base material (e.g., silicon or mold) with a signal distribution structure formed on the base material. The bridge die can be singulated from a bridge die wafer or panel. In some examples, the signal distribution structure of the bridge die can be formed in a back end of line (BEOL) process. However, the bridge die can be devoid of active circuity (e.g., transistors) formed during front end of line (FEOL) process. The BEOL signal distribution structure can comprise inorganic dielectric materials. In some examples, the signal distribution structure can comprise organic dielectric materials and can be formed in a buildup process over the base material. The signal distribution structure of the bridge die is oriented toward cavity substrate 102 and electronic module 101 and provides electrical interconnect between electronic module 101 and conductive structure 272 of cavity substrate 102.

FIG. 2N shows a cross-sectional view of electronic device 100 at a later stage of manufacture. In the example shown in FIG. 2N, encapsulant 298 can be provided. Techniques and structures used in providing encapsulant 298 can be similar to or the same as those described above for encapsulants 124 or 290, for example. Encapsulant 298 can be provided over electronic components 294, component 105, and electronic components 103. Encapsulant 298 can cover an upper side of electronic device 100. In some examples, a portion of encapsulant 298 can be removed to thin electronic device 100 and/or to expose electronic components 103 from encapsulant 298. In some examples, encapsulant 298 can be substantially coplanar with the exposed sides of electronic components 103. In various examples, encapsulant 298 can be coplanar with the lateral sides of cavity substate 102. In some examples, encapsulant 298 can extend over the lateral sides of cavity substrate 102.

FIG. 2O shows a cross-sectional view of electronic device 100 at a later stage of manufacture. In the example shown in FIG. 2O, lid 299 can be provided. In some examples, lid 299 can be coupled to electronic components 103 via an interface material. Lid 299 can be coupled to encapsulant 298 and/or electronic components 103 via an interface material. In some examples, lid 299 can comprise a heat spreader and can be coupled (e.g., thermally or mechanically) to electronic components 103 via a thermally conductive interface material. For example, the interface material can comprise a thermal interface material (TIM). Continuing the example, the TIM can comprise a metallic TIM such as indium-based TIM (e.g., In10Ag (10% Ag), In7Ag, In 5Ag, In 3Ag, or pure Indium). In some examples, TIM can comprise carbon-based graphite or carbon nanotubes. In some examples, TIM or interface material can also be interposed between encapsulant 298 and lid 299.

In some examples, lid 299 can comprise or be referred to as a heat spreader, cover, case, or housing. In some examples, lid 299 can be conformally applied (e.g., comprise a conformal coating applied) over the top or lateral sides of electronic components 103 and encapsulant 298. Lid 299 can cover the upper side of electronic device 100. Lid 299 can comprise an oversized heat spreader that extends outside a footprint of electronic module 101. Lid 299 can dissipate heat from electronic components 103 and can protect electronic device 100 from the external environment.

In various examples, external interconnects 297 can be provided. External interconnects 297 can be coupled to lower pads 280 of cavity substrate 102. In some examples, external interconnects 297 can comprise tin (Sn), silver (Ag), lead (Pb), copper (Cu), Sn—Pb, Sn37-Pb, Sn95-Pb, Sn—Pb—Ag, Sn—Cu, Sn—Ag, Sn—Au, Sn—Bi, or Sn—Ag—Cu. For example, external interconnects 297 can be provided by forming a conductive material including solder on lower pads 280 through a ball drop method followed by a reflow process. External interconnects 297 can comprise or be referred to as solder balls, bumps, pads, or pillars. In some examples, the sizes of external interconnects 297 can range from approximately 10 μm to approximately 1000 μm.

In some examples, external interconnects 297 can comprise conductive balls or bumps (e.g., solder balls, solder bumps, wafer bumps, solid core solder balls, or copper core solder balls). In some examples, external interconnects 297 can also comprise conductive pillars or posts, wires, lands or pads, and can comprise any of a conductive material (e.g., a metal or a conductive adhesive).

In some examples, electronic device 100 can be singulated through saw streets disposed around a perimeter of the depicted electronic device 100, thereby separating individual electronic devices 100. Singulation can be performed using, for example, mechanical cutting (e.g., sawing, cutting, polishing, or snapping), energy cutting (e.g., laser cutting, plasma cutting, etc.), or chemical cutting (e.g., etching or melting). In some examples, cavity substrate 102 can be singulated at an earlier stage of manufacture, and electronic device 100 can be processed as an individual package.

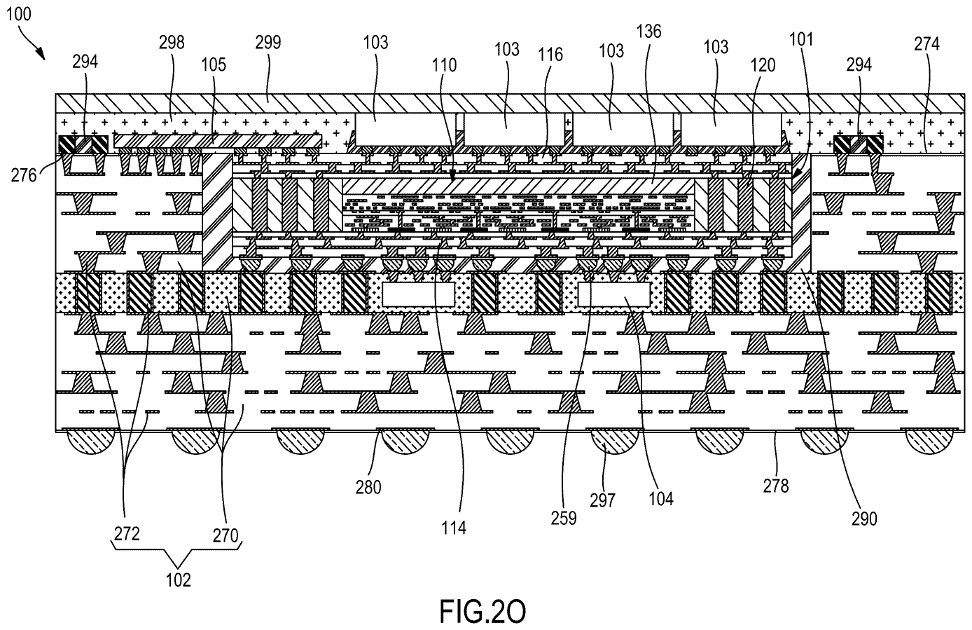

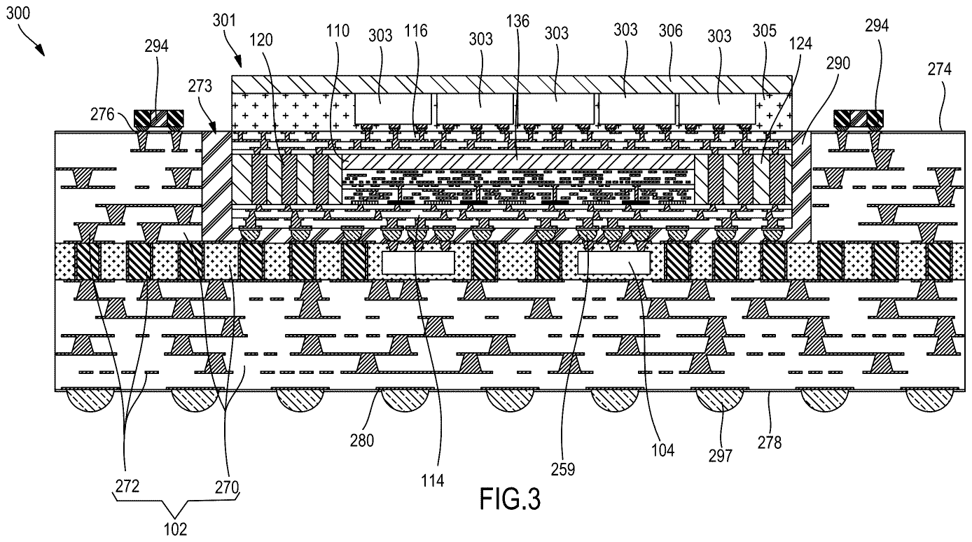

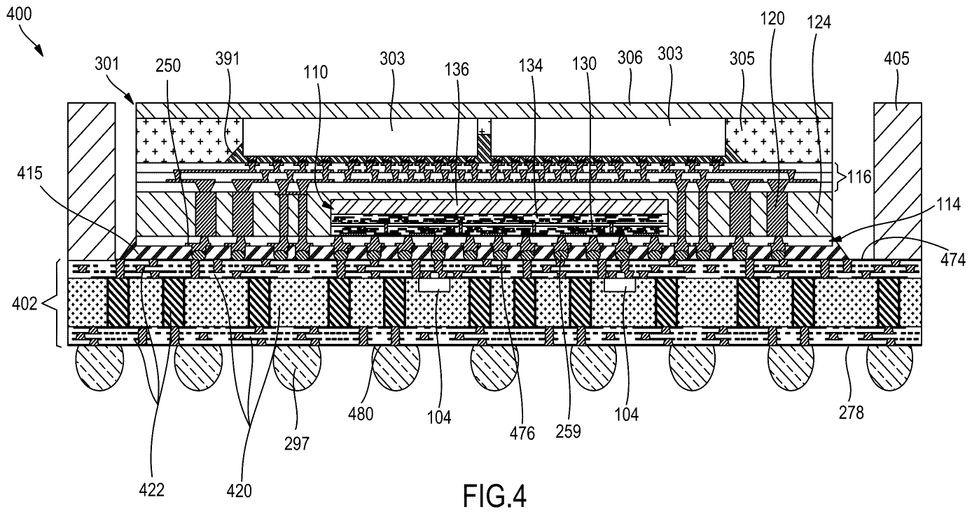

Referring now to FIG. 3, an example electronic device 300 is shown according to various embodiments. Various features of electronic device 300 can be similar to or the same as those of electronic device 100. Electronic device 300 can include electronic module 301 coupled to cavity substrate 102. Electronic module 301 can include electronic component 110, outer redistribution structures 114, inner redistribution structures 116, vertical interconnects 120 and encapsulant 124, as previously described with reference to electronic module 101. Electronic module 301 can further include electronic components 303 and upper encapsulant 305. In some examples, electronic module 301 can also include lid 306. Electronic components 303 can be similar to electronic components 103, as previously described. Upper encapsulant 305 can contact the lateral sides of electronic components 303, and in some examples can be located between electronic components 303 and inner redistribution structure 116. In some examples, and as shown in FIG. 4, an underfill 391, similar to underfill 291 (FIG. 2L), can be located between electronic components 303 and inner redistribution structure 116. Encapsulant 305 can surround the underfill 391 material in such examples.

In accordance with various examples, electronic components 303 and encapsulant 305 can be provided prior to singulation of electronic module 301. For example, electronic components 303 and encapsulant 305 can be provided after the steps show in FIG. 2G, and prior to singulation in FIG. 2H. In some examples, multiple electronic modules 301 can be singulated from one another by cutting through encapsulant 305, inner redistribution structure 116, encapsulant 124, and outer redistribution structure 114. In some examples, lid 306 can be provided prior to singulation, such that lid 306 is cut through during singulation. Sidewalls of encapsulant 305, inner redistribution structure 116, encapsulant 124, outer redistribution structure 114, and/or lid 306 can be substantially coplanar. Electronic module 301 can be made before placement in the aperture 273 defined by cavity substrate 102. In some examples, electronic module 301 can protrude above the upper side 274 of cavity substrate 102. Substrate encapsulant 290 can substantially fill the aperture 273 of cavity substrate 102. Substrate encapsulant 290 can fill a void between electronic module 301 and cavity substrate 102.

Referring now to FIG. 4, an example electronic device 400 is shown according to various embodiments. Various features of electronic device 400 can be similar to or the same as those of electronic device 300 in FIG. 3 and electronic device 100 in FIGS. 1A and 2B. Electronic device 400 can include base substrate 402 and electronic module 301. Base substrate 402 can differ in geometry from cavity substrate 102 (of FIG. 1). For example, base substrate 402 can comprise a substantially planar upper side 474. IPDs 104 can be embedded in base substrate 402. Stiffener 405 can be coupled to upper side 474 of base substrate 402 around a perimeter region. Base substrate 402 can include a dielectric structure 420 and a conductive structure 422. The elements, materials, and/or manufacturing techniques of dielectric structure 420 and conductive structure 422 can be similar to or the same as those of dielectric structure 270 and conductive structure 272, respectively, of cavity substrate 102.

In various examples, electronic module 301, as previously described with reference to FIG. 3, can be coupled to base substrate 402. Outer redistribution structure 114 of electronic module 301 can be between electronic component 110 and base substrate 402 and between vertical interconnects 120 and base substrate 402. Module interconnects 259 can be coupled between 250 of outer redistribution structure 114 and upper pads 476 of conductive structure 422. Upper pads 476 can be located along upper side 474 of base substrate 402. Conductive structure 472 of base substrate 402 can electrically couple upper pads 476 and lower pads 480 located along lower side 478 of base substrate 402. External interconnects 297 can be coupled to lower pads 480 of base substrate 402. Underfill 415 can be disposed between electronic module 301 and base substrate 402. Underfill 415 can surround module interconnects 259.

Underfill 391 can be provided between electronic components 303 and inner redistribution structure 116. Encapsulant 305 can be disposed around the sidewalls of electronic components 303 and underfill 391. In some examples, a gap can be defined between the sidewalls of electronic module 301 and the inner sidewalls of stiffener 405. Sidewalls of lid 306, encapsulant 305, inner redistribution structure 116, encapsulant 124, and outer redistribution structure 114 can be substantially coplanar in response to singulation of electronic module 301. One or more of the IPDs 104 can be vertically aligned with electronic component 110.

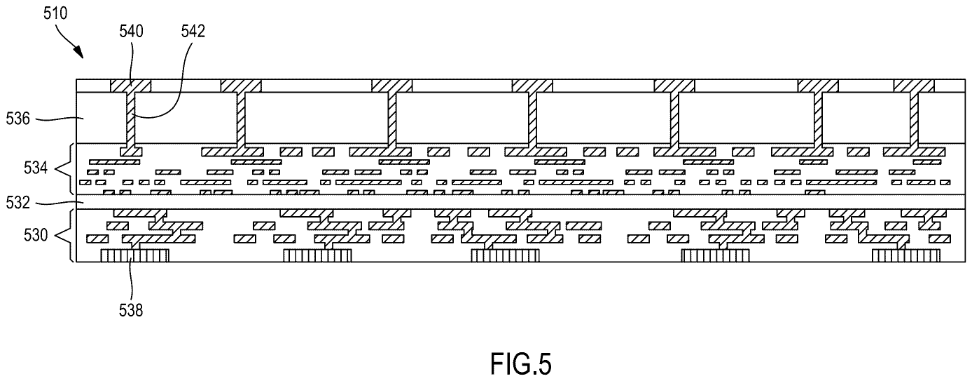

With reference to FIG. 5, an example electronic component 510 is shown in cross-sectional view, in accordance with various examples. Various features of, and techniques used to provide, electronic component 510 can be similar to or the same as those of electronic component 110 (of FIG. 1B). In the example of FIG. 5, electronic component 510 can comprise signal contact pads 540 disposed on a front side of electronic component 510. Signal contact pads 540 can be coupled to support structure 536. Conductive vias 542 can extend through support structure 536 to couple signal contact pads 540 with signal region 534.

In various examples, transistor region 532 can be disposed between signal region 534 and power region 530. Power contact pads 538 can be disposed on the backside of electronic component 510. Signal contact pads 540 can be disposed on a frontside of electronic component 510, opposite the backside of electronic component 510 and power contact pads 538.

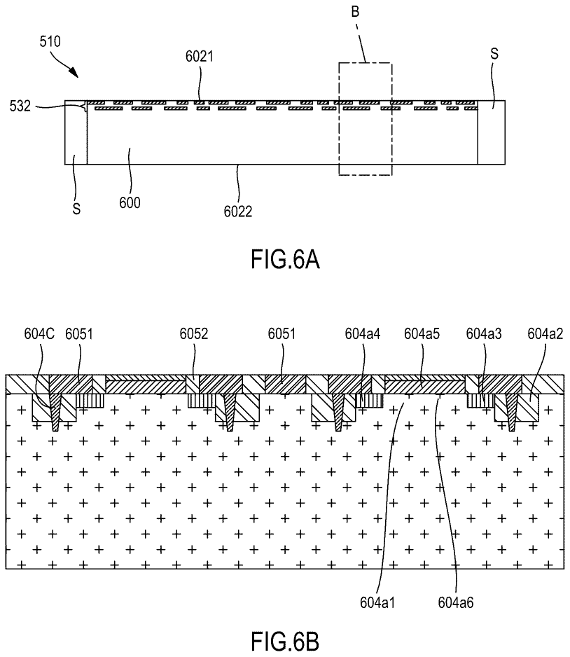

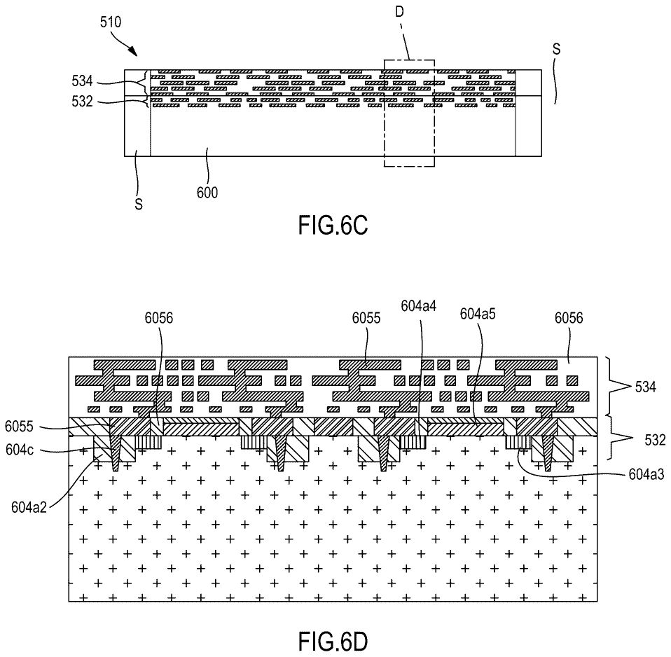

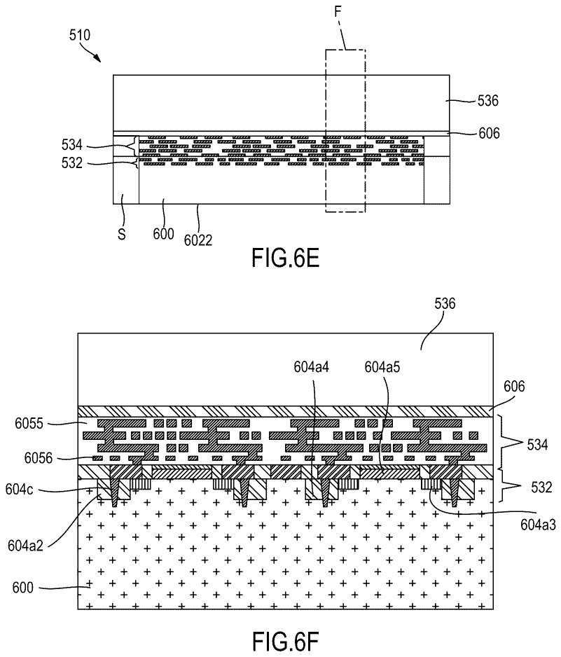

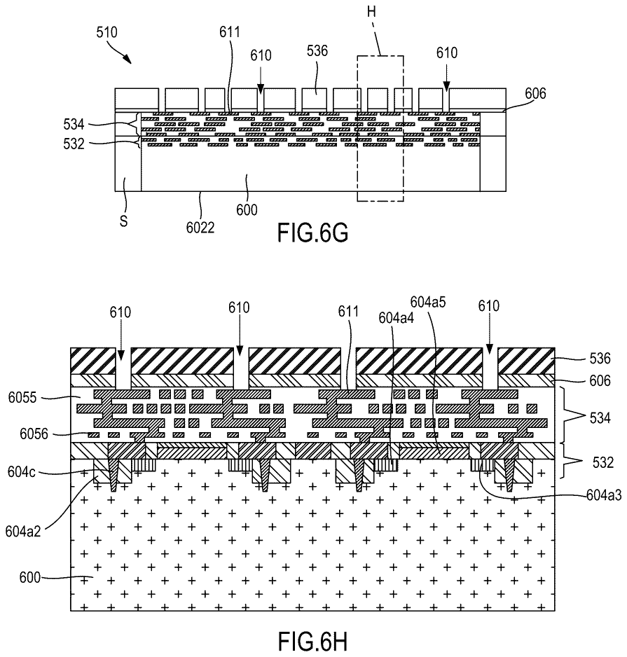

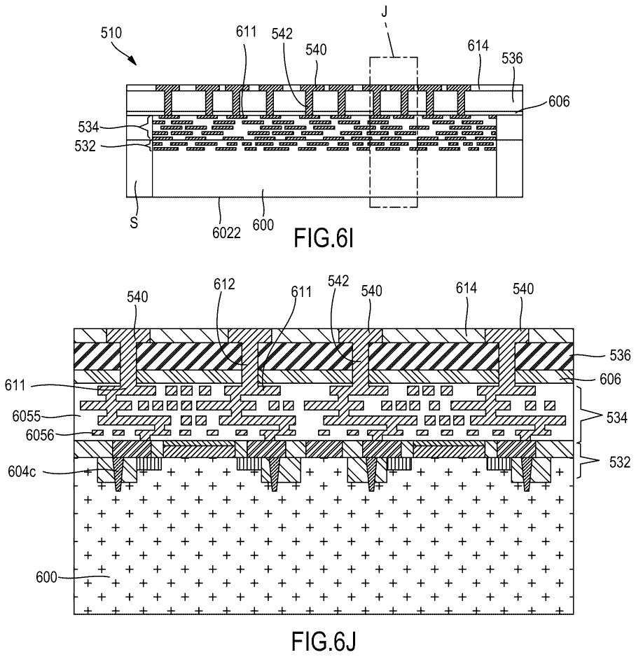

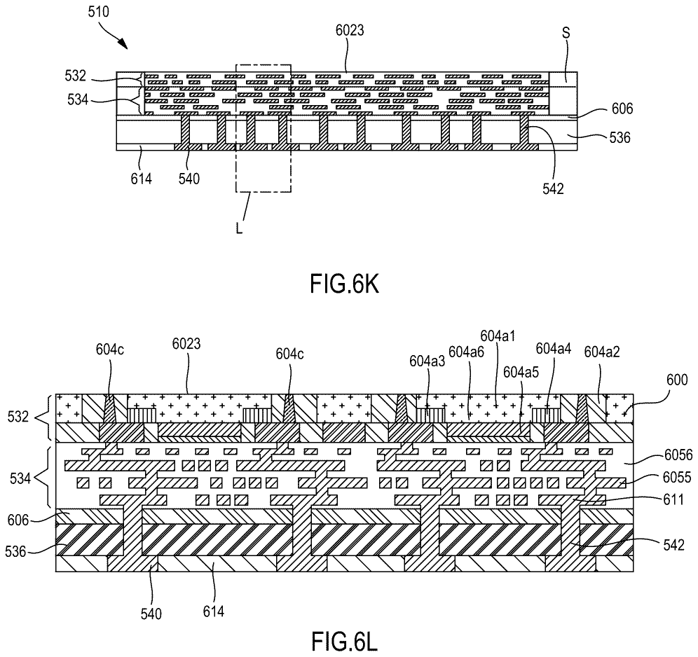

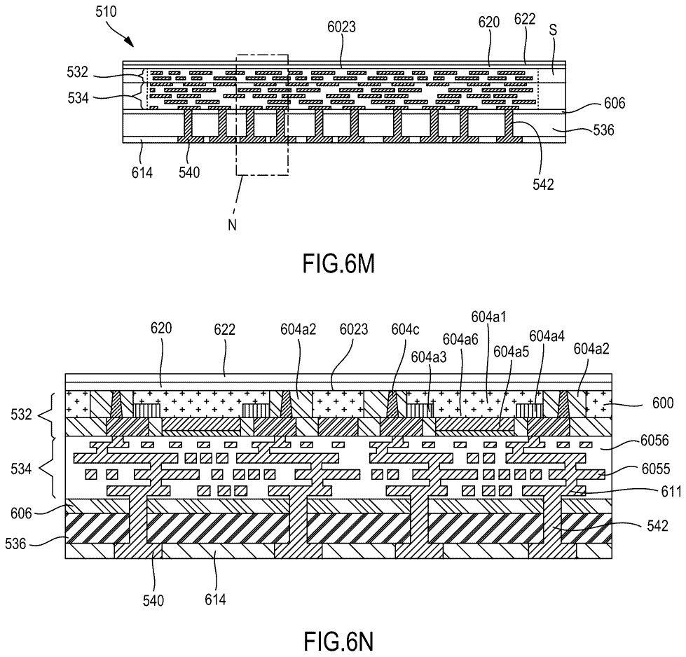

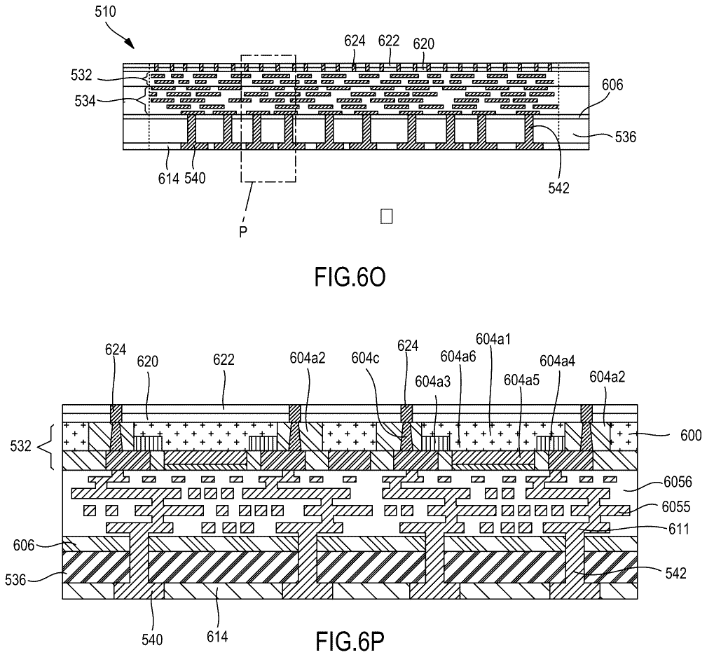

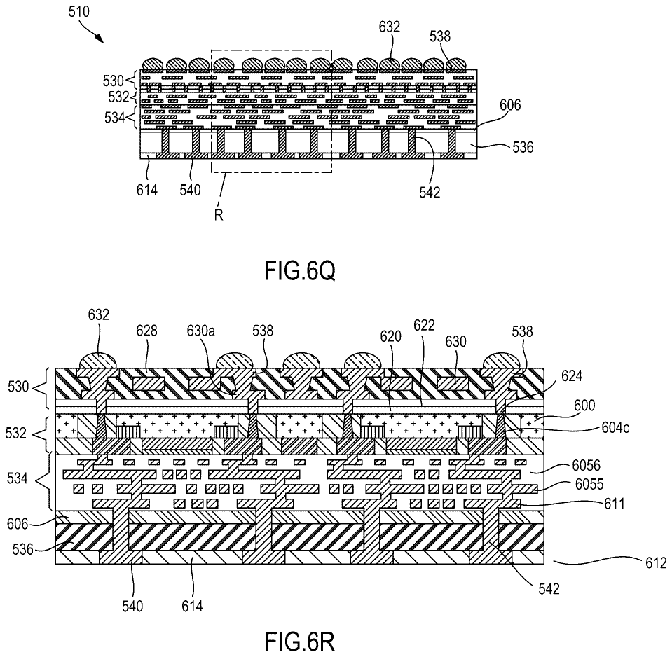

FIGS. 6A-6R depict an example method for making electronic component 510. FIG. 6A shows a cross-sectional view of electronic component 510 at an early stage of manufacture. FIG. 6B shows an enlarged view of electronic component 510 in region B of FIG. 6A.

In the example shown in FIGS. 6A and 6B, transistor substrate 600 can be provided. Transistor substrate 600 can comprise a semiconductor material or a wafer material, such as silicon (Si), germanium (Ge), gallium arsenide (GaAs), silicon carbide (SiC), or gallium nitride (GaN). Transistor substrate 600 can comprise or be referred to as a wafer, slice, substrate, single crystalline substrate, or crystalline substrate. In some examples, transistor substrate 600 can be provided through an ingot manufacturing process of making high-purity semiconductor solution and growing crystals at high temperature, an ingot slicing process of slicing an ingot to a uniform thickness by means of a diamond saw, a lapping and polishing process of processing a cut wafer as smooth as a mirror, and a fabrication (FAB) process of providing an active region on the surface of the wafer through a number of physical or chemical processes. The diameter of transistor substrate 600 can range from approximately 50 mm to approximately 300 mm. In some examples, the width or diameter of transistor substrate 600 can be greater than 300 mm (e.g., the width or diameter of transistor substrate 600 can be 600 mm). It will be appreciated that the larger the diameter of transistor substrate 600, the more electronic components 510 can be included in transistor substrate 600.

In some examples, the thickness of transistor substrate 600 can range from approximately 400 μm to approximately 1000 μm. In some examples, the thickness of transistor substrate 600 can be reduced to approximately 350 μm to approximately 500 μm through a wafer backgrinding process, wherein a portion of transistor substrate 600 is removed from side 6022. Transistor substrate 600 can comprise active side 6021 and side 6022 opposite active side 6021. Transistor substrate 600 can comprise multiple transistor regions 532 including power devices, integrated circuits, or memories provided along active side 6021. In some examples, the multiple transistor regions 532 can be arranged in rows and columns along active side 6021 and can be isolated or otherwise separated from one another by scribe lines or saw streets S. In accordance with various examples, transistor region 532 can be formed during front end of line (FEOL) processing.

In some examples, transistor region 532 can comprise semiconductor body 604a1, isolation region 604a2 (e.g., shallow trench isolation (STI)) provided around semiconductor body 604a1, source module 604a3 and drain module 604a4 provided in semiconductor body 604a1, and gate module 604a5 provided between source module 604a3 and drain module 604a4. In some examples, a sidewall spacer can cover the lateral sides of gate module 604a5. The region between source module 604a3 and drain module 604a4 in semiconductor body 604a1 can define or be referred to as a channel region 604a6. In some examples, isolation region 604a2, source module 604a3, drain module 604a4, gate module 604a5, and channel region 604a6 can comprise or be referred to as a transistor (e.g., a field-effect transistor (FET), a metal-oxide semiconductor field-effect transistor (MOSFET), an insulated gate bipolar transistor (IGBT), a complementary metal-oxide-semiconductor (CMOS), or other type of transistor). In some examples, transistor region 532 can include millions or billions of transistors. In some examples, transistor region 532 can also include capacitors and/or resistors.

In some examples, a conductive structure 6051 comprise horizontal traces and/or vertical vias can be electrically coupled to source module 604a3, drain module 604a4, or gate module 604a5. Dielectric material and/or layers 6052 can be located between components of conductive structure 6051 and components of transistor region 532 to electrically insulate them from one another. Dielectric structure 6051 can comprise one or more layers of inorganic dielectric material, such as for example, SiO2, Si3N4, SiOxNy (where x and y are each a natural number), or SiCN.

In accordance with various examples, power rails 604c can extend vertically through isolation region 604a2. Power rail 604c comprises a vertical conductive via and can be buried in isolation region 604a2. In some examples, power rail 604c can extend into the semiconductor material of transistor substrate 600. In some examples, power rail 604c can terminate at a surface of transistor substrate 600. In some examples, power rails 604c can be electrically coupled to source module 604a3 and drain module 604a4 through conductive structure 6051. In some examples, components (e.g., traces and/or vias) of conductive structure 6051 electrically coupling power rails 604c to components of transistor region 532 (e.g., to source module 604a3 and drain module 604a4) can be referred to as conductive structures for power, power components, conductive power components, power network, power delivery components, power structures, or similar terms or phrases. In one example, power rails 604c can support voltages of approximately 1 volt (V) to 350 V at approximately 50 ohms.

FIG. 6C shows a cross-sectional view of electronic device 510 at a later stage of manufacture, and FIG. 6D shows an enlarged view of electronic device 510 in region D of FIG. 6C. In the example shown in FIGS. 6C and 6D, signal network 534 is provided over transistor region 532.

In accordance with various examples, signal region 534 can be configured to interconnect the components (e.g., transistors, capacitors, or resistors) of transistor region 532. In some examples, signal region 534 can be formed using back end of line (BEOL) processing. Signal region 534 can comprise dielectric structure 6056 and conductive structure 6055.

Signal network 534 can comprise interleaved layers of dielectric structure 6056 and conductive structure 6055. Dielectric structure 6056 can be provided over transistor region 532 using physical vapor deposition (PVD), chemical vapor deposition (CVD), metal organic chemical vapor deposition (MOCVD), atomic layer deposition (ALD), low pressure chemical vapor deposition (LPCVD), plasma enhanced chemical vapor deposition (PECVD), printing, lamination, spin coating, spray coating, sintering, thermal oxidation, or any other suitable deposition process. Dielectric structure 6056 can comprise one or more layers of inorganic dielectric material, such as for example, SiO2, Si3N4, SiOxNy (where x and y are each a natural number), or SiCN.

In various examples, conductive structure 6055 can be provided within or interleaved with layers of dielectric structure 6056. Conductive structure 6055 can be formed using PVD, CVD, MOCVD, ALD, LPCVD, PECVD, electrolytic plating, electroless plating process, or any other suitable metal deposition process. In some examples, conductive structure 6055 can comprise one or more layers of Cu, Al, Au, Ag, Ni, Ti, TiW, Pd, Pt, or other suitable electrically conductive materials.

Components (e.g., traces and/or vias) of conductive structure 6055 electrically coupling the components of transistor region 532 to one another can be referred to as conductive structures for signals, signal structures, signal components, conductive signal components, signal network, signal transmission components, or similar terms or phrases. Signal network 534 can support signals at lower voltages than power network 530. In one example, the signal network 534 can support voltages of approximately 0.001 V to 10 V.

FIG. 6E shows a cross-sectional view of electronic device 510 at a later stage of manufacture, and FIG. 6F shows an enlarged view of electronic device 510 in region F of FIG. 6E. In the example shown in FIGS. 6E and 6F, support structure 536 is coupled to transistor substrate 600.

In accordance with various examples, support structure 536 can be provided over signal region 534 of transistor substrate 600 and can be coupled to dielectric structure 6055 of signal network 534. Support structure 536 can comprise a semiconductor material, such as Si, Ge, GaAs, SiC, or GaN, a wafer material, or a glass material. Support structure 536 can comprise or be referred to as a wafer, slice, single crystalline substrate, or crystalline substrate. In some examples, support structure 536 can be provided through an ingot manufacturing process of making high-purity semiconductor solution and growing crystals at high heat, an ingot slicing process of slicing an ingot to a uniform thickness by means of a diamond saw, and a lapping and polishing process of processing a cut wafer as smooth as a mirror.

In some examples, support structure 536 can comprise or be referred to as a non-pattern wafer (NPW), a recycled wafer, or a dummy wafer. The diameter (or width) and thickness of support structure 536 can be similar to the diameter (or width) and thickness of transistor substrate 600. In some examples, the diameter or width of support structure 536 can range from approximately 50 mm to approximately 300 mm. In some examples, the diameter or width of support structure 536 can be greater than 300 mm (e.g., 600 mm). The thickness of support structure 536 can range from approximately 400 μm to approximately 1000 μm in some examples. In some examples, the thickness of support structure 536 can range from approximately 350 μm to approximately 500 μm. In some examples, the thickness of support structure 536 can range from approximately 100 μm to approximately 800 μm. In some examples, the thickness of support structure 536 can range from approximately 10 μm to approximately 150 μm.

In accordance with various examples, support structure 536 comprises dielectric 606. Dielectric 606 can be provided on the lower side of support structure 536 (e.g., on the side of support structure 536 that is oriented toward transistor substrate 600). Dielectric 606 can comprise or be referred to as an insulating material, an inorganic material, a dielectric structure, or an inorganic dielectric structure. The material of dielectric 606 can be similar to or the same as the material of dielectric structure 6056 described above. In some examples, dielectric 606 can comprise SiO2, Si3N4, SiOxNy, or SiCN. In some examples, dielectric 606 can be provided using an oxidation process (e.g., by oxidizing support structure 536) or a deposition process. For example, dielectric 606 can be provided through PVD, CVD, MOCVD, ALD, LPCVD, or PECVD. The thickness of dielectric 606 can range from approximately 1000 angstrom (Å) to approximately 1 μm.

In accordance with various examples, support structure 536 can be coupled to transistor substrate 600. For example, dielectric 606 can be bonded to dielectric structure 6056. In some examples, the bonding process can be referred to as a wafer-to-wafer bonding process. The wafer-to-wafer bonding process can form a bond interface between adjacent surfaces or sides of the bonded wafers. In some examples, a planarization process can be performed before the wafer-to-wafer bonding process. For example, dielectric 606 and/or dielectric structure 6056 can be planarized prior to bonding. In some examples, a planarization process can be performed in a manner similar to a chemical mechanical polishing (CMP) process. For example, the planarization process can be performed by providing a chemical slurry on a polishing pad and pressing and rotating dielectric 606 or dielectric structure 6056 on the polishing pad. In some examples, the average surface roughness (Ra) of dielectric 606 and dielectric structure 6056 after the planarization process can range from approximately 0.1 nm (nanometers) to approximately 5 nm. Planarizing the surfaces of dielectric 606 and dielectric structure 6056 to within the foregoing surface roughness range can increase the interaction force between atoms and the strength of the bond interfaces. Planarizing the surfaces also can decrease the frequency and size of voids and can prevent generation of voids between the bond interfaces.

In some examples, the bonding process can be performed by applying pressure in a state where dielectric 606 and dielectric structure 6056 face each other and are in contact with each other. For example, the bonding process can include applying, by means of a pressure applying tool (e.g., a chuck), mechanical pressure to side 6022 of transistor substrate 600 and to the opposing side of support structure 536, opposite dielectric 606. In some examples, the compressive force applied to dielectric 606 and dielectric structure 6056 can range from approximately 10 Newton (N) to approximately 1000 N. In accordance with various examples, the force applied can be greater than or equal to approximately 100 N to increase the likelihood that dielectric 606 and dielectric structure 6056 will sufficiently bond to each other. In some examples, the force applied can be less than approximately 1000 N to decrease or reduce the likelihood of damage to support structure 536 or transistor substrate 600.

In some examples, an annealing process can be performed during, after, or in place of the pressure applying process. The annealing temperature can range from approximately 250° C. to approximately 400° C. In some examples, if the annealing temperature is less than approximately 300° C., dielectric 606 and dielectric structure 6056 may not sufficiently bond to one another. In some examples, if the annealing temperature is greater than approximately 400° C., an already-formed active region can be damaged or the characteristics of the active region can be changed. In some examples, the annealing temperature can be increased by using thermal rays or radio frequency (RF). In some examples, the radio frequency can be ultra-high frequency or millimeter waves or can comprise microwave waves in a frequency band ranging from approximately 2 GHz to approximately 5 GHz or from approximately 30 MHz to approximately 60 MHz.

In some examples, the time associated with an annealing process using thermal rays can range from approximately 1 hour to approximately 10 hours. In other examples, the annealing process using radio frequency (RF) can be completed in approximately 30 seconds to approximately 90 seconds (e.g., rapid annealing). In accordance with various examples, the rapid annealing can improve a bonding strength by inducing covalent bonds before the hydrophilicity of dielectric 606 and dielectric structure 6056 can be reduced. In accordance with various examples, the annealing process using radio frequency (RF) tends to increase the temperature of only the region participating in bonding, (e.g., selective annealing of each region is possible). In this regard, the annealing process using radio frequency (RF) can be advantageous for controlling defects compared to annealing using a hot thermal wire. While dielectric 606 and dielectric structure 6056 are shown as distinct structures, it is contemplated and understood that after bonding, dielectric 606 and dielectric structure 6056 may be indistinguishable from one another in some examples.

In accordance with various examples, the bond between dielectric structure 6056 and dielectric 606 can initially start as a Van der Waals bond that progresses to a covalent bond through time or temperature. In accordance with various examples, the bonding between dielectric structure 6056 and dielectric 606 can be achieved at relatively low temperatures through surface activation of dielectric structure 6056 and dielectric 606 prior to bonding. In some examples, surface activation of dielectric structure 6056 and dielectric 606 can include generating hydrogen (H) on the surfaces of dielectric structure 6056 and dielectric 606 through plasma treatment, oxygen (O) particles separated from water or air during plasma treatment can bind to the hydrogen (H) on the surfaces of dielectric structure 6056 and dielectric 606, and hydroxyl (OH) groups can be induced on the surfaces of dielectric structure 6056 and dielectric 606. With the surfaces of dielectric structure 6056 and dielectric 606 “activated” bonding can occur at lower temperatures. For example, the initial Van der Waals bonds can form at room temperature (e.g., at temperatures ranging from approximately 20° C. to approximately 30° C.). Covalent bonds between dielectric structure 6056 and dielectric 606 can also be formed at room temperature; however, in various embodiments, an annealing process can be performed to decrease the time associated with covalent bond formation. In some examples, the temperature of the annealing process can range from approximately 25° C. to approximately 200° C. and the time can range from 0.5 to 20 hours. In some examples, the annealing process can include applying a temperature of approximately 150° C. for between 1.0 to 3.0 hour(s). The annealing process can improve bonding strength, reduce bonding time, and increase yields by inducing the conversion of the Van der Walls bonds to covalent bonds.

FIG. 6G shows a cross-sectional view of electronic device 510 at a later stage of manufacture, and FIG. 6H shows an enlarged view of electronic device 510 in region H of FIG. 6G. In the example shown in FIGS. 6G and 6H, openings 610 can be formed through support structure 536 and dielectric 606 to expose terminals 611 of conductive structure 6055.

In some examples, openings 610 can be provided by sequentially penetrating support structure 536 and dielectric 606. In some examples, the openings 610 can be provided at locations corresponding to terminals 611. Terminals 611 can comprise conductive signal structures of conductive structure 6055. Openings 610 can be provided by laser drilling, chemical etching, deep reactive ion etching (DRIE), or any other suitable formation technique. In various examples, the depths of openings 610 can be equal to the total combined thickness of support structure 536 and dielectric 606. In response to the hole providing process, the upper side of the conductive signal structures 6055 (e.g., terminals 611) can be exposed through support structure 536 and dielectric 606.

In some examples, a dielectric layer (or an insulating layer) can be provided on the inner walls of openings 610. When the inner walls of openings 610 contain silicon, the dielectric layer can comprise an inorganic film such as SiO2 or Si3N4. When the inner walls of the openings 610 contain glass or ceramic, the dielectric layer can comprise an organic film such as polyimide (PI), benzocyclobutene (BCB), or polybenzoxazole (PBO). The dielectric layer can be provided by PVD, CVD, MOCVD, ALD, LPCVD, or PECVD. In some examples, regions of the dielectric layer provided at the bottoms of the openings 610 can be removed such that the dielectric layer remains on the side walls of the openings 610. Removal of regions of the dielectric layer can be done by laser or chemical etching. The thickness of the dielectric layer can range from approximately 1 nm to approximately 30 nm, from approximately 2 nm to approximately 25 nm, from approximately 3 nm to approximately 20 nm, from approximately 4 nm to approximately 15 nm, or any other suitable thickness. Different materials used in the dielectric layer can be provided in different thicknesses suitable to the characteristics of the selected materials. The dielectric layer can improve electrical reliability by inhibiting or reducing the electrical shorts of conductive vias later formed in openings 610.

In some examples of the barrier-providing process, an adhesion-and-diffusion preventing layer can be provided on the inner walls (e.g., side walls) of the dielectric layer. The adhesion-and-diffusion preventing layer can comprise Ta, TaN, TiN, or Ru. The adhesion-and-diffusion preventing layer can be provided by sputtering, PVD, CVD, MOCVD, ALD, LPCVD, or PECVD. In some examples, the adhesion-and-diffusion preventing layer can be provided on the bottom side defining the openings 610. For example, the adhesion-and-diffusion preventing layer can be provided on the region of terminals 611 that defines the bottoms of openings 610. The thickness of the adhesion-and-diffusion preventing layer can range from approximately 4 nm to approximately 10 nm. The adhesion-and-diffusion preventing layer can improve adhesion characteristics of a seed layer or a conductor coupled to the inner walls defining the openings in a subsequent stage. The adhesion-and-diffusion preventing layer tends to prevent metal ions from diffusing into the inner walls of the openings.

FIG. 6I shows a cross-sectional view of electronic device 510 at a later stage of manufacture, and FIG. 6J shows an enlarged view of electronic device 510 in region J of FIG. 6I. In the example shown in FIGS. 6I and 6J, conductive vias 542 are provided in openings 610, and passivation structure 614 and signal pads 540 are provided over the exposed side of support structure 536.

In accordance with various examples, conductive vias 542 can extend through and penetrate support structure 536 and dielectric 606. In some examples, conductive vias 542 can comprise through-silicon vias (TSVs) or through glass vias (TGVs). In some examples, conductive vias 542 can be provided by forming a barrier in the hole 610, providing a seed layer over the barrier, and providing a conductor (e.g., electroplating conductive material) on the seed layer. The conductor can comprise Cu, Al, Ni, Au, Ag, Pt, or any other suitable conductive material. In some examples, the holes can be filled with the conductor by an electrolytic plating method. The conductive vias 542 can contact and be electrically coupled to terminals 611 of conductive structure 6055.

In some examples, after providing conductive vias 542, a planarization process or a CMP process can be performed. In some examples, after the planarization process, the upper sides of conductive vias 542 can be substantially coplanar with the upper side of support structure 536. Passivation structure 614 can be provided over support structure 536 and conductive vias 542. Openings can be formed in passivation structure 614 to expose conductive vias 542. Singal pads 540 electrically coupled to conductive vias 542 can be provided in the openings defined by passivation structure 614. In some examples, signal pads 540 can be formed prior to deposition of passivation structure 614. In some examples, one or more additional conductive layer(s) and/or passivation layer(s) can be formed (e.g., interleaved) between conductive vias 542 and signal pads 540.

FIG. 6K shows a cross-sectional view of electronic device 510 at a later stage of manufacture, and FIG. 6L shows an enlarged view of electronic device 510 in region L of FIG. 6K. In the example shown in FIGS. 6K and 6L, a portion of transistor substrate 600 can be removed from side 6022, thereby forming new backside 6023 (also referred to herein as upper side 6023 of semiconductor body 604a1).

In some examples, a chemical mechanical polishing (CMP) process can be performed on back side 6022 (FIG. 6I). The CMP process can be applied to semiconductor body 604a1 of transistor substrate 600. The CMP process can be performed by pressing transistor substrate 600, with support structure 536 coupled thereto, to a polishing pad while supplying chemical slurry to the rotating polishing pad. In some examples, the polishing pad and transistor substrate 600 can rub against each other while rotating in opposite directions. In some examples, the back side 6022 of transistor substrate 600 can be softened by the chemical slurry, and the softened back side 6022 can be removed by being ground by a mechanical force. In some examples, the speed of CMP polishing can be proportional to the product of pressure and speed (relative speed). In some examples, after the CMP process, a cleaning process for removing and drying impurities can be performed.

In some examples, the CMP process can include thinning transistor substrate 600 at least until exposing buried power rail 604c or isolation region 604a2. In this way, the upper side (as oriented in FIGS. 6K and 6L) of buried power rail 604c or isolation region 604a2 can be exposed through side 6023 of semiconductor body 604a1. In some examples after CMP, the upper side of buried power rail 604c or the upper side of isolation region 604a2 can be coplanar with the upper side 6023 of semiconductor body 604a1. In some examples, by providing a slurry with selectivity, the removal rate of the different structure or materials can be varied during the CMP process and the upper side of buried power rail 604c or the upper side isolation region 604a2 can be lower than or recessed from (i.e., not coplanar with) the upper side 6023 of semiconductor body 604a1. In some examples, the upper side 6023 of semiconductor body 604a1, as shown in the orientation of FIGS. 6K and 6L, can be higher than or can protrude from the upper side of buried power rail 604c or the upper side of isolation region 604a2. In some examples, after CMP, the thickness of transistor substrate 600 (i.e., transistor region 532) can range from approximately 40 nm to approximately 1000 nm, approximately 100 nm to approximately 500 nm, or 130 nm to approximately 250 nm.

FIG. 6M shows a cross-sectional view of electronic device 510 at a later stage of manufacture, and FIG. 6N shows an enlarged view of electronic device 510 in region N of FIG. 6M. In the example shown in FIGS. 6M and 6N, passivation layer 620 and passivation layer 622 are provided over transistor substate 600.

In accordance with various examples, a passivation structure can be provided over the upper side 6023 of transistor substrate 600. The passivation structure can comprise one or more passivation layers. A passivation layer 620 can be provided over the upper side 6023 of transistor substrate 600. For example, passivation layer 620 can be coupled to the upper sides of semiconductor body 604a1, buried power rails 604c, and isolation region 604a2. In some examples, passivation layer 620 can contact exposed buried power rail 604c and isolation region 604a2. Passivation layer 620 can comprise or be referred to as an insulating material, an inorganic material, a dielectric structure, or an inorganic dielectric structure. In some examples, passivation layer 620 can comprise SiO2, Si3N4, SiOxNy, or SiCN. Passivation layer 620 can be provided by oxidation or deposition. In some examples, passivation layer 620 can be provided by PVD, CVD, MOCVD, ALD, LPCVD, or PECVD. The thickness of passivation layer 620 can range from approximately 50 nm to approximately 150 nm. Passivation layer 620 together with semiconductor body 604a1 can provide excellent thermal conductivity. Passivation layer 620 together with semiconductor body 604a1 tend to have low hardness, which can reduce the wear imparted on the sawing tool used in singulation. In some examples, a CMP process can be performed on the upper side of passivation layer 620, prior to providing passivation layer 622.

In accordance with various examples, passivation layer 622 can be provided on the upper side of passivation layer 620. Passivation layer 622 can comprise or be referred to as an insulating material, an inorganic material, a dielectric structure, or an inorganic dielectric structure. In some examples, passivation layer 622 can comprise SiO2, Si3N4, SiOxNy, or SiCN. In some examples, passivation layer 622 can be provided using techniques or structures similar to those described above for passivation layer 620.

In some examples, the material of passivation layer 622 can be different from the material of passivation layer 620. For example, passivation layer 620 can comprise SiO2, and passivation layer 622 can comprise Si3N4, SiOxNy, or SiCN. In some examples in which passivation layer 620 comprises Si3N4, SiOxNy, or SiCN, passivation layer 622 can comprise SiO2. The thickness of passivation layer 622 can range from approximately 50 nm to approximately 500 nm. Passivation layer 622 together with passivation layer 620 can provide excellent thermal conductivity. Passivation layer 622 together with passivation layer 620 can have a low hardness, which tends to reduce the wear imparted on a sawing tool used in singulation. In some examples, a CMP process can be performed on the upper side of passivation layer 622.

FIG. 6O shows a cross-sectional view of electronic device 510 at a later stage of manufacture, and FIG. 6P shows an enlarged view of electronic device 510 in region P of FIG. 6O. In the example shown in FIGS. 6O and 6P, conductive vias 624 can be provided through passivation layer 620 and passivation layer 622.

In accordance with various examples, conductive vias 624 can extend through and penetrate passivation layer 622 and passivation layer 620. In some examples, conductive vias 624 comprise one or more power vias. Power vias can penetrate passivation layer 622 and passivation layer 620. Power vias can be coupled to the upper side of buried power rails 604c. Power vias can be coupled to conductive structure 6051 to deliver or receive power via buried power rails 604c. For example, power vias can be coupled to traces of conductive structure 6051 that are coupled to buried power rail 604c.

In some examples, conductive vias 624 can be provided by forming a hole or opening, providing a barrier in the hole, providing a seed layer over the barrier, and providing a conductor over the seed layer. In some examples, holes can be provided by sequentially penetrating passivation layer 622 and passivation layer 620. The holes can be provided by laser drilling, chemical etching, DRIE, or any other suitable formation technique. In some examples, the diameter of the holes can range from approximately 15 nm to approximately 300 nm, from approximately 20 nm to approximately 275 nm, from approximately 25 nm to approximately 250 nm, or from approximately 30 nm to approximately 200 nm. Example measurements of distance given in the present disclosure are meant for example purposes only and are not limiting.

In various examples, the depths of the holes can range from approximately 100 nm to approximately 650 nm. For example, the holes extending to buried power rails 604c can have a depth between approximately 100 nm and approximately 650 nm, which can correspond to the combined thickness of passivation layer 620 and passivation layer 622. In response to the hole providing process, the upper side of buried power rail 604c can be exposed through first and passivation layers 620, 622. In some examples, isolation region 604a2 can serve as an etch stop. For example, the lower sides of the holes can be formed, provided, or defined by the upper side of isolation region 604a2.

In some examples, a dielectric layer (or an insulating layer) can be provided on the inner walls of the holes. When the inner walls of the holes contain silicon, the dielectric layer can comprise an inorganic film such as SiO2 or Si3N4. When the inner walls of the holes contain glass or ceramic, the dielectric layer can comprise an organic film such as polyimide (PI), benzocyclobutene (BCB), or polybenzoxazole (PBO). The dielectric layer can be provided by PVD, CVD, MOCVD, ALD, LPCVD, or PECVD. In some examples, regions of the dielectric layer provided at the bottoms of the holes can be removed such that the dielectric layer remains on the side walls of the holes. Removal of regions of the dielectric layer can be done by laser or chemical etching. The thickness of the dielectric layer can range from approximately 1 nm to approximately 30 nm, from approximately 2 nm to approximately 25 nm, from approximately 3 nm to approximately 20 nm, from approximately 4 nm to approximately 15 nm, or any other suitable thickness. Different materials used in the dielectric layer can be provided in different thicknesses suitable to the characteristics of the selected materials. The dielectric layer can improve electrical reliability by inhibiting or reducing the electrical shorts of conductive vias 624.

In some examples of the barrier-providing process, an adhesion-and-diffusion preventing layer can be provided on the inner walls (e.g., side walls) of the dielectric layer. The adhesion-and-diffusion preventing layer can comprise Ta, TaN, TiN, or Ru. The adhesion-and-diffusion preventing layer can be provided by sputtering, PVD, CVD, MOCVD, ALD, LPCVD, or PECVD. In some examples, the adhesion-and-diffusion preventing layer can be provided on the bottom side defining the holes. For example, the adhesion-and-diffusion preventing layer can be provided on the region of buried power rail 604c that defines the bottoms of the holes. The thickness of the adhesion-and-diffusion preventing layer can range from approximately 4 nm to approximately 10 nm. The adhesion-and-diffusion preventing layer can improve adhesion characteristics of a seed layer or a conductor coupled to the inner walls defining the holes in a subsequent stage. The adhesion-and-diffusion preventing layer tends to prevent metal ions from diffusing into the inner walls of the holes.

In some examples of the seed layer providing process, a seed layer can be provided on the inner walls of the adhesion-and-diffusion preventing layer. In some examples, the seed layer can comprise Ti, TiW, Cu, or Au. The seed layer can be provided by sputtering, PVD, CVD, MOCVD, ALD, LPCVD, or PECVD. In some examples, the seed layer can be deposited on or over areas of buried power rail 604c corresponding to the bottoms of the holes. In some examples, the adhesion-and-diffusion-preventing layer can be interposed between the buried power rail 604c and the seed layer. The thickness of the seed layer can range from approximately 1 nm to approximately 10 nm, or can be any suitable thickness for the seed layer to fit on the inner walls defining a hole and allow space for the conductor inside the hole. The seed layer can provide a path for the flow of current when a conductor is electroplated onto the inner walls of the holes.

In some examples of the conductor providing process, a conductor can be provided on the seed layer. In some examples, the conductor can fill the holes (e.g., the hole can contain or include the dielectric layer, adhesion-and-diffusion-preventing layer, seed layer, and conductor). The conductor can comprise Cu, Al, Ni, Au, Ag, Pt, or any other suitable conductive material. In some examples, the holes can be filled with the conductor by an electrolytic plating method. In general, when a metal is plated at a low current density, it tends to be easier to form a uniform plating layer, enabling defect-free filling but having a slow plating speed. Slow plating speed tends to increase the filling time. Conversely, when high-current-density plating is employed, the plating speed tends to increase so that the filling time can be shortened, but the entrances of the holes can become clogged, which can cause defects. Accordingly, the current density related to plating can be adjusted in consideration of various process variables, such as hole diameters or hole depths. The diameter of the conductor can range from approximately 10 nm to approximately 260 nm, from approximately 20 nm to approximately 230 nm, from approximately 30 nm to approximately 200 nm, or any other suitable diameter to fill open space between the inner walls of the hole or between adjacent sides of the seed layer on the inner walls. The length of the conductor in a vertical direction can range from approximately 100 nm to approximately 650 nm, depending on the depth of the hole. The conductor can be electrically connected to buried power rail 604c.

In some examples, after providing conductive vias 624, a planarization process or a CMP process can be performed. In some examples, after the planarization process, the upper sides of conductive vias 624 can be coplanar with the upper side of passivation layer 622.

FIG. 6Q shows a cross-sectional view of electronic device 510 at a later stage of manufacture, and FIG. 6R shows an enlarged view of electronic device 510 in region R of FIG. 6Q. In the example shown in FIGS. 6Q and 6R, power network 630 can be provided over passivation layer 622.

In accordance with various embodiments, power network 630 can comprise dielectric structure 628 and conductive structure 630. Dielectric structure 628 can comprise one or more dielectric layers made of dielectric material (e.g., polymer, polyimide (PI), benzocyclobutene (BCB), polybenzoxazole (PBO), bismaleimide triazine (BT), resin, Ajinomoto Buildup Film (ABF), Si3N4, SiO2, SiON, etc.) and interleaved between layers of conductive structure 630. Dielectric structure 628 can be provided by PVD, CVD, MOCVD, ALD, LPCVD, PECVD, or any other suitable deposition process. Conductive structure 630 can comprise one or more conductive layers defining signal distribution elements (e.g., traces, vias, pads, conductive paths, UBMs, etc.) interleaved between layers of dielectric structure 628. Conductive structure 630 can comprise Al, Cu, Au, Ag, Ni, Pd, or other suitable conductive material. Conductive structure 630 can be formed using PVD, CVD, MOCVD, ALD, LPCVD, PECVD, electrolytic plating, electroless plating process, or any other suitable metal deposition process. Conductive structure 630 can distribute power signals in a vertical direction and a lateral direction through dielectric structure 628. In some examples, conductive structure 630 can comprise a power network configured to deliver and distribute power within electronic device 510, and conductive structure 6055 can comprise a signal network configured to deliver and distribute signals within electronic device 510.

Conductive structure 630 can comprise inward terminals 630a and power contact pads 538. Inward terminals 630a can be coupled to conductive vias 624. For example, inward terminals 630a can be coupled to or contact power vias 624. In some examples, the lower sides of inward terminals 630a can be coplanar with the lower side of dielectric structure 628, as shown in the orientation of FIG. 6R. Power contact pads 538 can be provided at the upper side of power network 530 (i.e., the side opposite inward terminals 630a). Conductive structures (e.g., traces and vias) of conductive structure 630 can electrically couple inward terminals 630a and power contact pads 538. Power contact pads 538 can comprise or be referred to as pads, two-step pads, lands, or UBM. In some examples, the upper sides of power contact pads 538 can be coplanar with the upper side of dielectric structure 628, as shown in the example of FIG. 6R. In some examples, power contact pads 538 can protrude from the upper side of dielectric structure 628, as shown in the orientation of FIG. 6R. In some examples, individual layers of dielectric structure 628 and conductive structure 630 can range from approximately 6 μm to approximately 30 μm in thickness. In some examples, the thickness of the individual layers of dielectric structure 628 and conductive structure 630 can be greater than the thickness of individual layers of dielectric structure 6056 and conductive structure 6055, respectively. In some examples, the line width (i.e., width of individual trace) and line spacing (i.e., lateral distance between adjacent traces) of conductive structure 630 can be greater than the line width and/or line spacing of conductive structure 6055.

In some examples, external interconnects 632 can be provided on power contact pads 538. External interconnects 632 can comprise power interconnects coupled to vias 624 via conductive structure 630. External interconnects 632 can be provided on power contact pads 538 by a plating or deposition process. External interconnects 632 can comprise or be referred to as conductive pillars, conductive balls, conductive bumps, or solder balls. In some examples, a conductive pillar can be provided on contact pads 538 by plating or depositing Cu, Al, Au, Ag, Ni, or SnAg on contact pads 538. In some examples, flux or flowable material can be provided on contact pads 538, conductive balls are dropped on the flux, and the conductive balls can then be provided on contact pads 538 through a reflow process or a laser-assisted bonding process. In some examples, the conductive balls can comprise Sn, Ag, Pb, Cu, Sn—Pb, Sn37-Pb, Sn95-Pb, Sn—Pb—Ag, Sn—Cu, Sn—Ag, Sn—Au, Sn—Bi, or Sn—Ag—Cu. In some examples, the thicknesses or widths of external interconnects 632 can range from approximately 0.01 mm to approximately 0.5 mm. External interconnects 632 can serve to couple electronic device 510 to an external device.

In various examples, singulation can be performed. During singulation, transistor substrate 600, which includes multiple electronic components 510, can be separated into individual, discrete electronic components 510 by sawing along saw street S (FIGS. 6O and 6P). In some examples, a diamond blade wheel or a laser beam can be used for singulation. The singulation process can include cutting through passivation structure 614, support structure 536, dielectric 606, signal region 534, transistor region 532, passivation layer 620, passivation layer 622, and power region 530 using a sawing tool. After the singulation process, the lateral sides passivation structure 614, support structure 536, dielectric 606, signal region 534, transistor region 532, passivation layer 620, passivation layer 622, and power region 530 can be coplanar with one another.

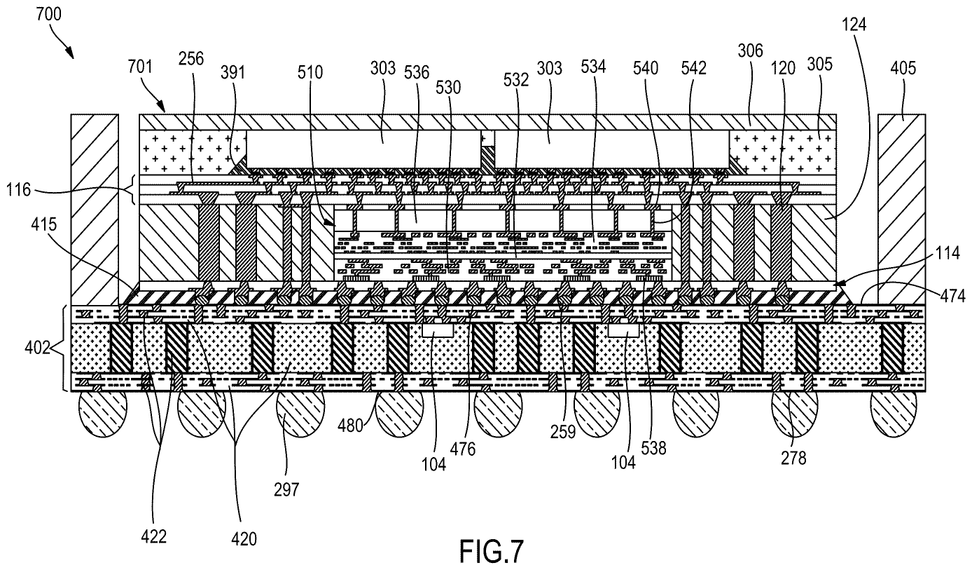

Referring now to FIG. 7, an example electronic device 700 is shown according to various embodiments. Various features of electronic device 700 can be similar to or the same as those of electronic device 400, electronic device 300 and/or electronic device 100, as previously described. Electronic device 700 can include module 701, which may be similar to module 301 and/module 101. Module 701 includes electronic component 510, outer redistribution structure 114, inner redistribution structure 116, vertical interconnects 120, encapsulant 124, encapsulant 305, and electronic components 303. Inner redistribution structure 116 can contact and be coupled to signal pads 540 of electronic components 510. Electrical signals can be sent between signal region 534 of electronic component 510 and electronic components 303 via conductive vias 542, signal pads 540, and conductive structure 256 of inner redistribution structure 116. Electrical signals can be transmitted through the conductive vias 542 and signal contact pads 540 from electronic component 110 to electronic components 303. In accordance with various examples, power can be delivered via base substrate 402 to power network 530 of electronic component 510 through inner redistribution structure 114. In accordance with various examples, power signals can be provided via base substrate 402 to electronic components 303 through inner redistribution structure 114, conductive vias 120, and inner redistribution structure 116.

Electronic devices and related methods can include passive devices integrated into a substrate such as, for example, in a PCB core. An electronic component can be coupled to the embedded passive devices with a short path for excellent power control. In some examples, the electronic component can be coupled to the embedded passive devices across component interconnects exposed at the upper side of the substrate. Some examples can deliver power or signals through the back side of an electronic component directly to stacked memory die or other electronic components. Thickness can thus be reduced, and high performance connections can be realized due to short electronic paths.

The present disclosure includes reference to certain examples; however, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure not be limited to the examples disclosed, but that the disclosure will include all examples falling within the scope of the appended claims.

What is claimed is:

1. An electronic device, comprising:
a cavity substrate comprising inner sidewalls and a recessed side that define an aperture, wherein an integrated passive device (IPD) is embedded in the cavity substrate with the recessed side disposed over the IPD;
an electronic module disposed in the aperture and over the IPD, the electronic module comprising:
a lower redistribution structure coupled to the recessed side of the cavity substrate;
a first electronic component including a power region coupled to the lower redistribution structure, a transistor region over the power region, and a signal region over the transistor region;
an upper redistribution structure coupled to an upper side of the first electronic component; and
a vertical interconnect disposed lateral to a sidewall of the first electronic component, the vertical interconnect coupled to the lower redistribution structure and the upper redistribution structure;
second electronic components disposed over the electronic module and coupled to the upper redistribution structure; and
a lid coupled to an upper side of the second electronic components.

2. The electronic device of claim 1, further comprising an encapsulant substantially coplanar with the upper side of the second electronic components and disposed between the lid and the cavity substrate.

3. The electronic device of claim 1, further comprising a bridge die coupled to the cavity substrate and coupled to the upper redistribution structure of the electronic module.

4. The electronic device of claim 1, wherein the first electronic component comprises a conductive via extending from a signal contact pad, through the power region, through the transistor region, and to the signal region.

5. The electronic device of claim 1, wherein a terminal of the IPD is coupled with the lower redistribution structure.

6. The electronic device of claim 5, wherein a power contact pad of the first electronic component is coupled to the IPD through the lower redistribution structure.

7. The electronic device of claim 5, wherein the cavity substrate further comprises:
conductive vias disposed around lateral sides of the IPD; and
an encapsulant disposed around the conductive vias and the IPD, wherein the recessed side of the cavity substrate comprises the encapsulant.

8. The electronic device of claim 1, further comprising a passive device coupled to the upper side of the cavity substrate.

9. The electronic device of claim 1, wherein the lid completely covers the upper side of the cavity substrate.

10. The electronic device of claim 1, wherein the electronic module includes the second electronic components and the lid.

11. The electronic device of claim 10, wherein the upper side of the cavity substrate is completely outside a footprint of the lid.

12. An electronic device, comprising:
a substrate including an integrated passive device (IPD) embedded in a central region of the substrate;
an electronic module coupled to the substrate, the electronic module comprising:
a first electronic component including a power region oriented towards the substrate, a transistor region over the power region, a signal region over the transistor region, and a support structure over the transistor region;
an upper redistribution structure coupled to the support structure;
a vertical interconnect disposed lateral to a sidewall of the first electronic component and coupled to the upper redistribution structure;
second electronic components disposed over the electronic module and coupled to the upper redistribution structure; and
a lid coupled to an upper side of the second electronic components.

13. The electronic device of claim 12, wherein the electronic module further comprises:
a signal contact pad disposed over the support structure and coupled to the upper redistribution structure; and
a conductive via extending from the signal region, through the support structure, to the signal contact pad.

14. The electronic device of claim 12, further comprising a stiffener coupled to a perimeter region of the substrate with the electronic module disposed central to the stiffener.

15. The electronic device of claim 12, wherein the substrate further comprises:
conductive vias disposed around lateral sides of the IPD; and
an encapsulant disposed around the conductive vias and the IPD.

16. A method of manufacturing an electronic device, comprising:
providing a substrate including an integrated passive device (IPD) embedded in a central region of the substrate;
providing an electronic module over the substrate, the electronic module comprising:
a lower redistribution structure coupled to the central region of the substrate;
a first electronic component including a power region coupled to the lower redistribution structure, a transistor region over the power region, and a signal region over the transistor region; and
an upper redistribution structure coupled to an upper side of the first electronic component;
providing second electronic components over the upper redistribution structure; and
providing a lid coupled to the second electronic components.

17. The method of claim 16, wherein providing the electronic module over the substrate includes providing the second electronic components over the upper redistribution structure and providing the lid coupled to the second electronic components.

18. The method of claim 16, further comprising providing a bridge die coupled to the upper redistribution structure and coupled to the substrate.

19. The method of claim 16, wherein the central region of the substrate defines a bottom of an aperture, and wherein the electronic module is provided in the aperture.

20. The method of claim 16, further comprising providing a stiffener over a perimeter region of the substrate, the stiffener disposed around the electronic module.
